(19) United States
(12) Patent Application Publication
(10) Pub. No.: US 2021/0013167 A1
(43) Pub. Date: Jan. 14, 2021

(54) MICROELECTRONIC DEVICE WITH SOLDER-FREE PLATED LEADS

(71) Applicant: Texas Instruments Incorporated, Dallas, TX (US)

(72) Inventor: Nazila Dadvand, Richardson, TX (US)

(73) Assignee: Texas Instruments Incorporated, Dallas, TX (US)

(21) Appl. No.: 16/506,494

(22) Filed: Jul. 9, 2019

(51) Int. Cl. H01L 23/00; H01L 21/78

(52) U.S. Cl. CPC H01L 24/13; H01L 24/11; H01L 24/94; H01L 21/78; H01L 2224/13082; H01L 2224/13147; H01L 2224/11462; H01L 2224/13155; H01L 2224/13164; H01L 2224/13166; H01L 2224/13181; H01L 2224/13184; H01L 2224/1318; H01L 2224/13144

(57) ABSTRACT

A microelectronic device has a solder-free package lead extending through an electrically non-conductive package structure to an exterior of the microelectronic device. The package lead includes a pillar contacting a terminal on a die and extending partway through the package structure, and an external lead electrically coupled to the pillar and extending to an exterior of the microelectronic device. The package lead is free of a solder joint. The microelectronic device may be formed by forming an access cavity package structure, to expose the pillar, and forming the external lead by a plating process. The microelectronic device may be formed by providing an external lead lamina containing the external lead, and forming a plated metal joint by a plating process that connects the external lead to the pillar.

### FIELD

This disclosure relates to the field of microelectronic devices. More particularly, this disclosure relates to package leads in microelectronic devices.

### BACKGROUND

A microelectronic device requires connections between a die of the microelectronic device and external leads of a package containing the die. Wire bonds may not be sufficiently robust to handle high currents reliably. Such a microelectronic device commonly has solder bump bonds between the die and the external leads, to handle the high currents. However, solder joints exhibit reliability problems, such as formation of intermetallic compounds that have high electrical resistance and reduce reliability of the microelectronic device.

### SUMMARY

The present disclosure introduces a microelectronic device with a solder-free package lead and a method for forming the microelectronic device. The microelectronic device has a die, and the electrically conductive package lead contacting the die and extending through an electrically non-conductive package structure to an exterior of the microelectronic device. The package lead includes a pillar contacting the die and extending partway through the package structure, and an external lead electrically coupled to the pillar and extending to an exterior of the microelectronic device. The package lead is free of a solder joint.

In one aspect, the microelectronic device may be formed by forming the electrically non-conductive package structure on the die, covering the pillar. An access cavity is formed in the electrically non-conductive material, to expose the pillar. An external lead mask is formed over a plating seed layer on the package structure. The external lead is formed by a plating process.

In another aspect, the microelectronic device may be formed by providing an external lead lamina containing the external lead extending through the external lead lamina, and aligning the external lead with the pillar, proximate to the pillar. A plating solution is introduced between the external lead lamina and the die, the plating solution contacting the external lead and the pillar. A plated metal joint is formed by a plating process that connects the external lead to the pillar.

### BRIEF DESCRIPTION OF THE VIEWS OF THE DRAWINGS

FIG. 1A through FIG. 1M are cross sections of a microelectronic device having a solder-free package lead, depicted in stages of an example method of formation.

FIG. 2A through FIG. 2J are cross sections of another microelectronic device having a solder-free package lead, depicted in stages of another example method of formation.

FIG. 3A through FIG. 3E are cross sections of a microelectronic device having a solder-free package lead, depicted in stages of a further example method of formation.

FIG. 4A through FIG. 4C are cross sections of a microelectronic device having a solder-free package lead, depicted in stages of another example method of formation.

FIG. 5A through FIG. 5R are cross sections of a microelectronic device having a solder-free package lead, depicted in stages of a further example method of formation.

FIG. 6A through FIG. 6I are cross sections of a microelectronic device having a solder-free package lead, depicted in stages of another example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A microelectronic device has a package lead which is solder-free, extending from a terminal of the die to an exterior of the microelectronic device. The package lead includes a pillar electrically coupled to the terminal, and an external lead electrically coupled to the pillar and extending to an exterior of the microelectronic device. The package lead is free of a solder joint. The microelectronic device may be formed by forming the external lead by a plating process on a plating seed layer contacting the pillar. Alternatively, the microelectronic device may be formed by coupling the pillar and the external lead by a plated metal joint using a plating process.

It is noted that terms such as top, back, over, above, under, below, interior, and exterior may be used in this disclosure. These terms should not be construed as limiting the position or orientation of a structure or element, but should be used to provide spatial relationship between structures or elements.

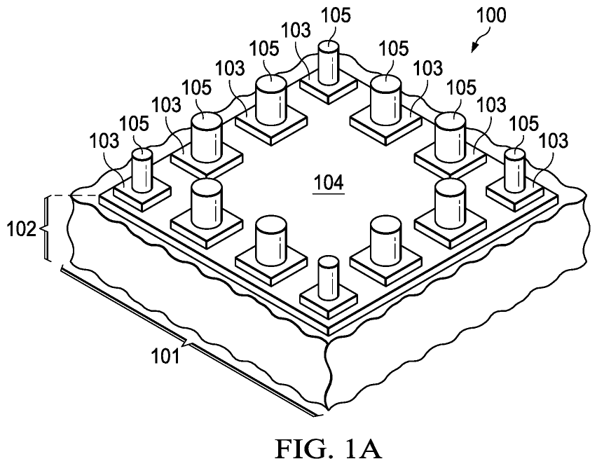

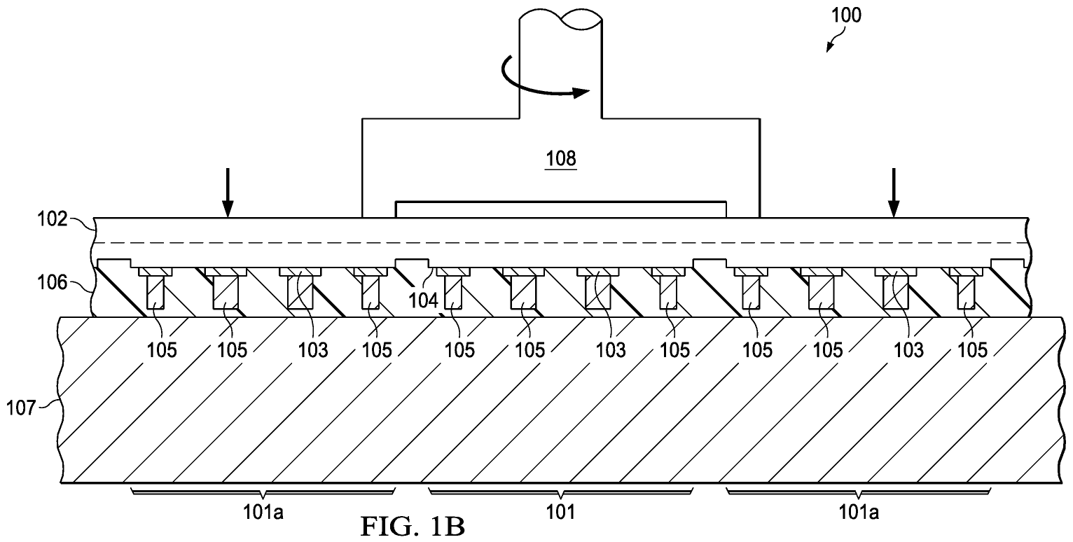

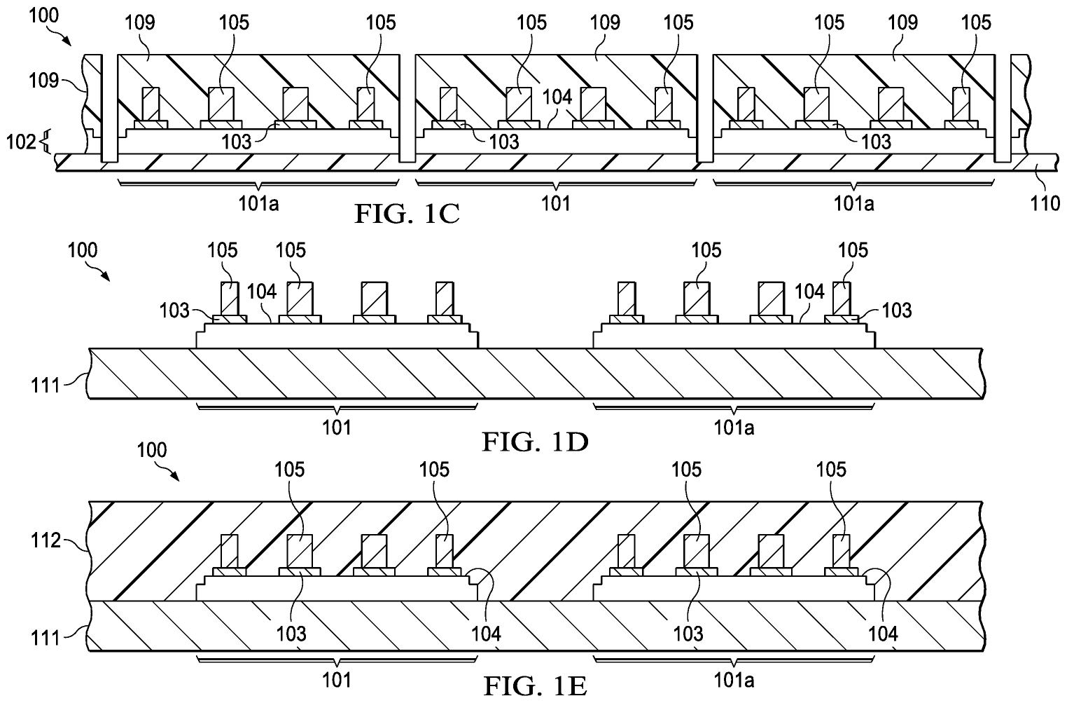

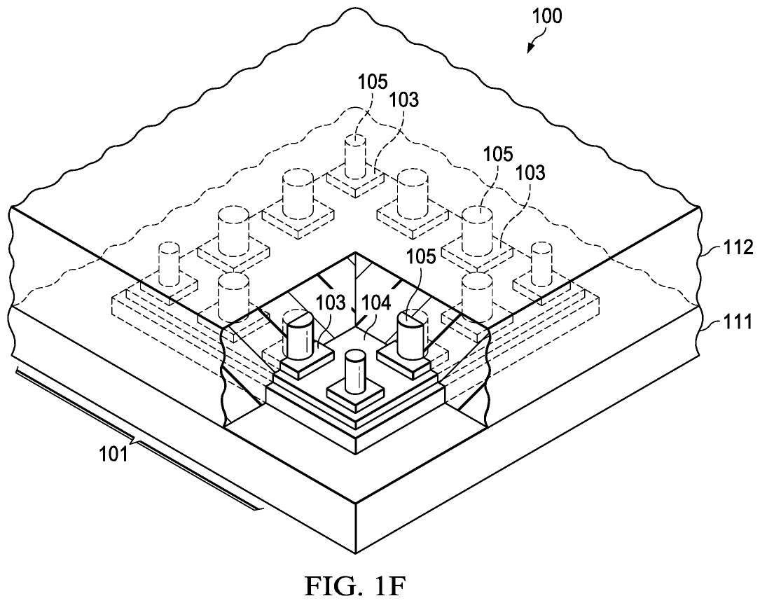

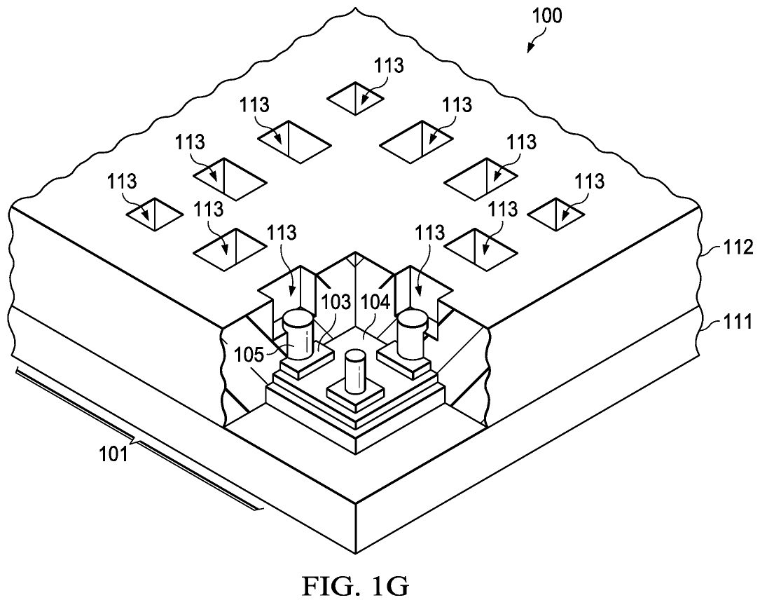

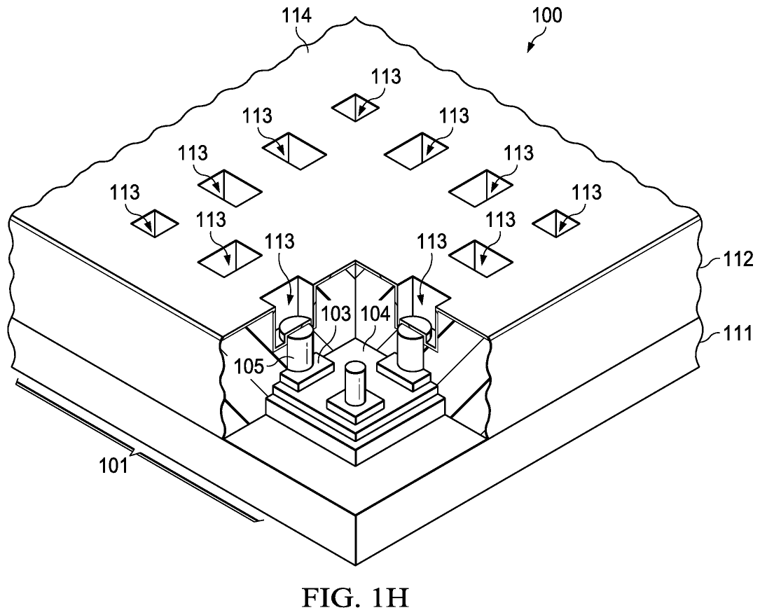

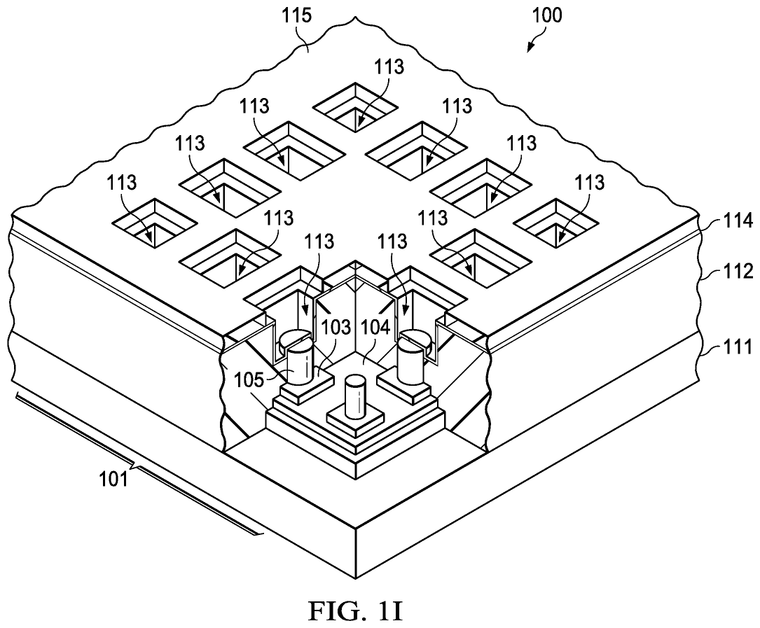

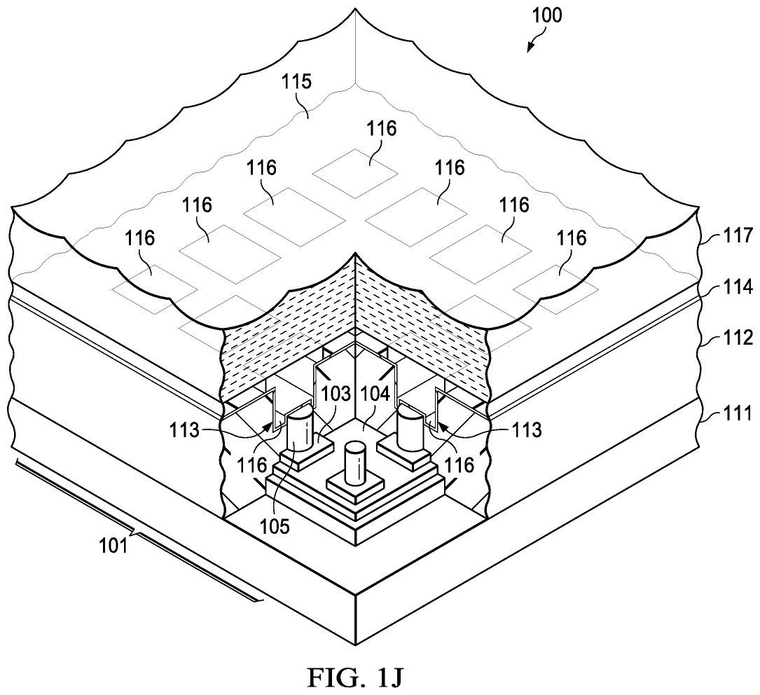

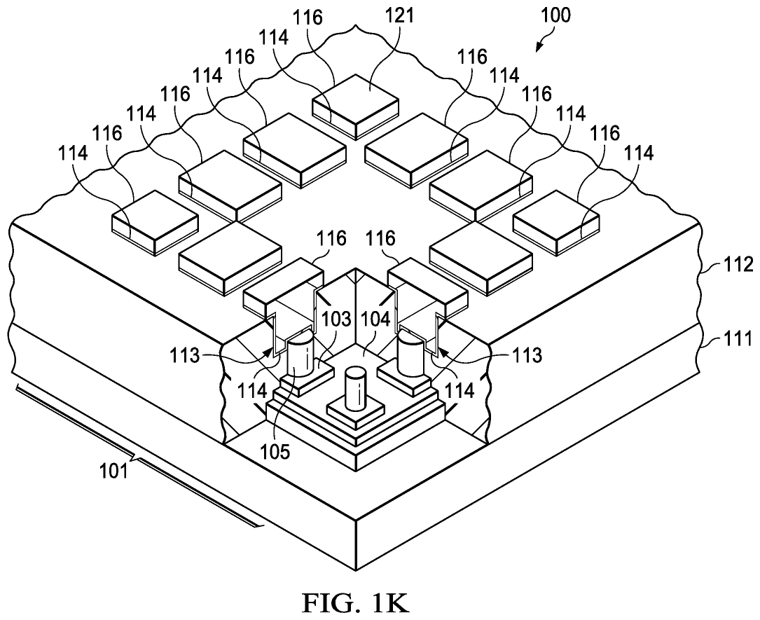

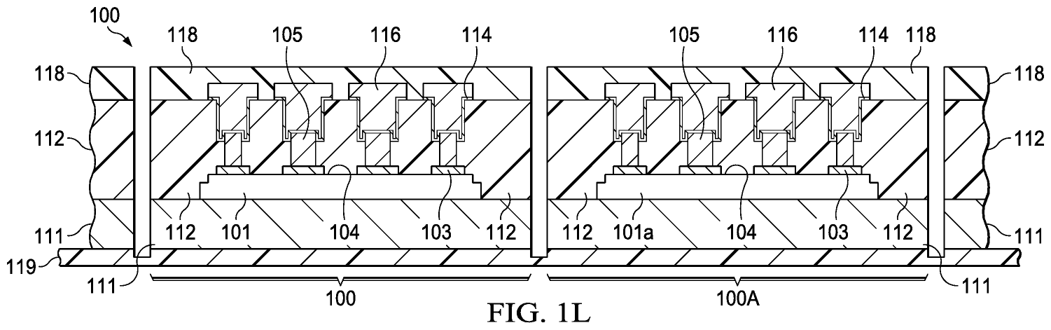

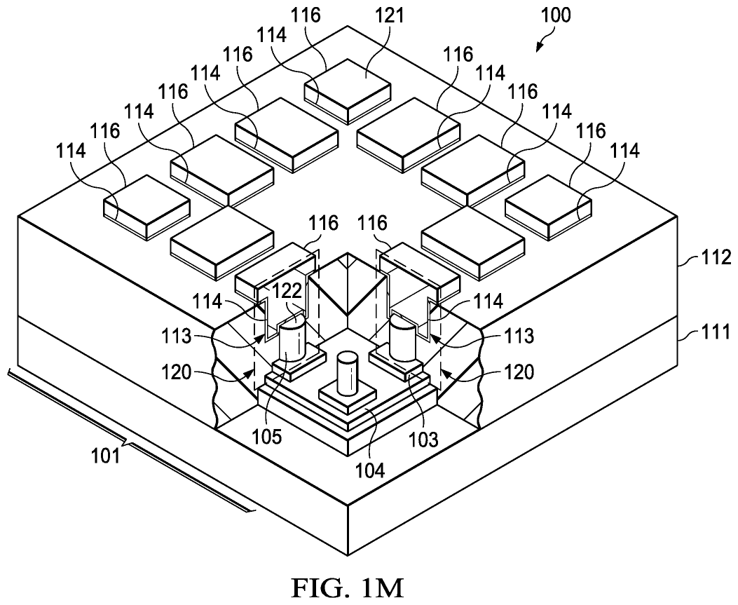

FIG. 1A through FIG. 1M are cross sections of a microelectronic device having a solder-free package lead, depicted in stages of an example method of formation. Referring to FIG. 1A, the microelectronic device 100 includes a die 101 which is part of a workpiece 102 containing additional die, not shown in FIG. 1A. The die 101 may be implemented as an integrated circuit, a discrete semiconductor device, a microelectrical mechanical system (MEMS) device, an electro-optical device, or a microfluidics device, for example. The workpiece 102 may be implemented as a semiconductor wafer, a MEMS substrate, or a microfluidics substrate, for example. The die 101 has terminals 103 at a component surface 104 of the die 101. The terminals 103 are electrically conductive, and may be implemented as bond pads containing aluminum, copper, nickel, palladium, platinum, or gold. Alternatively, the terminals 103 may be implemented as through-substrate vias containing tungsten, aluminum, or copper.

Pillars 105 of the microelectronic device 100 are disposed on the terminals 103. In one version of this example, the pillars 105 may include primarily copper, that is, more than 50 weight percent copper, for example as formed by a copper plating process, optionally with another metal such as nickel or gold. Having more than 50 weight percent copper in the pillars 105 may advantageously provide low electrical resistance in the pillars 105 and a low cost for the microelectronic device 100. In another version of this example, the pillars 105 may include primarily other metals, such as nickel, cobalt, palladium, or gold. In a further version, the pillars 105 may include any platable metal-rich electrically conductive material. The pillars 105 may also include interface layers, not shown in FIG. 1A, in direct contact with the terminals 103. The interface layers may include metals such as nickel, titanium, tungsten, tantalum, or molybdenum, which may improve adhesion of the pillars 105 to the terminals 103. The interface layers may also reduce diffusion of copper from the pillars 105 into the die 101.

Referring to FIG. 1B, the workpiece 102 may optionally be thinned from a back surface, located opposite from the component surface 104. A protective coating 106 may be applied to the component surface 104, covering the pillars 105, to protect the pillars 105 and the component surface 104. The workpiece 102 may be mounted on a grinder chuck 107 with the protective coating 106 contacting the grinder chuck 107. A grinder head 108 may remove material from the workpiece 102 to provide a desired thickness for the die 101 of the microelectronic device 100, and additional die 101a in the workpiece 102. The protective coating 106 may be removed after the workpiece 102 is thinned.

Referring to FIG. 1C, the die 101 is singulated from the workpiece 102. A first singulation coating 109 may be applied to the component surface 104, covering the pillars 105, to protect the pillars 105 and the component surface 104 during a first singulation process. The workpiece 102 may be mounted on a first singulation film 110 to hold the die 101 and the additional die 101a in place during the first singulation process. The die 101 may be singulated from the workpiece 102 by a saw process, a mechanical scribe process, a laser scribe process, an etching process, or other singulation process. After the first singulation process is completed, the first singulation coating 109 may be removed and the die 101 and the additional die 101a may be demounted from the first singulation film 110.

Referring to FIG. 1D, the die 101 and the additional die 101a are mounted on a package plate 111. The package plate 111 may include materials such as ceramic, aluminum, or copper to provide a heatsink for the die 101. The die 101 may be attached to the package plate 111 by an adhesive, a solder, or other die attach material.

Referring to FIG. 1E, a package structure 112 is formed on the die 101 and the additional die 101a, covering the pillars 105 and the component surface 104, and on the package plate 111 between the die 101 and the additional die 101a. The package structure 112 is electrically non-conductive, and may include, for example, epoxy, benzocyclobutane (BCB), silicone, polyurethane, or low transition temperature glass. Other non-conductive material for the package structure 112 is within the scope of this example. The package structure 112 may be formed by injection molding, slump molding, spin coating, spraying, additive extrusion, material jetting, a photolithographic process, or other process.

FIG. 1F is a cutaway view of the microelectronic device 100 after the package structure 112 is formed on the die 101. The package structure 112 extends onto the package plate 111 adjacent to the die 101.

Referring to FIG. 1G, access cavities 113 are formed in the package structure 112 to expose the pillars 105. The access cavities 113 may be formed, for example, by forming a etch mask, not shown in FIG. 1G, which exposes areas for the access cavities 113, and removing material from the package structure 112 where exposed by the etch mask, by a plasma etch process. Alternatively, the access cavities 113 may be formed by a maskless process using laser ablation or ultrasonic machining.

Referring to FIG. 1H, an interface layer 114 is formed on the package structure 112, extending into the access cavities 113 and contacting the pillars 105. The interface layer 114 is electrically conductive. The interface layer 114 may include, for example, an adhesion sublayer contacting the package structure 112, and a plating seed sublayer on the adhesion sublayer. The adhesion sublayer may include metals that exhibit strong adhesion to the package structure 112, such as titanium, tantalum, or tungsten. The plating seed sublayer may include copper to facilitate a subsequent plating process. The interface layer 114 may be formed by one or more sputter processes, metal organic chemical vapor deposition (MOCVD) processes, evaporation processes, or other thin film processes.

Referring to FIG. 1I, an external lead mask 115 is formed on the interface layer 114, exposing the interface layer 114 in areas for subsequently-formed external leads 116, shown in FIG. 1J. The external lead mask 115 exposes the interface layer 114 in the access cavities 113. The external lead mask 115 may include photoresist and may be formed by a photolithographic process. Alternatively, the external lead mask 115 may include organic polymer material and may be formed by an additive process such as material jetting or material extrusion. The external lead mask 115 may have a thickness of 1 micron to 100 microns, for example, to provide a desired thickness of the external leads 116.

Referring to FIG. 1J, the external leads 116 are formed on the interface layer 114 where exposed by the external lead mask 115. The external leads 116 are formed by a plating process using a plating bath 117. The plating process may be implemented as an electroplating process or an electroless plating process. The plating bath 117 may include copper, so that the external leads include primarily copper, that is, more than 50 weight percent copper, which may advantageously provide low electrical resistance in the external leads 116 and low fabrication cost for the microelectronic device 100. Other metals for the external leads 116, such as nickel, cobalt, palladium, or gold, are within the scope of this example. The external leads 116 may include any platable metal-rich electrically conductive material. The external leads 116 extend into the access cavities 113, so that the pillars 105 are coupled to the external leads 116 through the interface layer 114. In one version of this example, the external leads 116 may extend to a top surface of the external lead mask 115, as depicted in FIG. 1J. In another version, the external leads 116 may extend to a level below the top surface of the external lead mask 115. In a further version, the external leads 116 may extend above the top surface of the external lead mask 115. After the external leads 116 are formed, the microelectronic device 100 is separated from the plating bath 117. The external lead mask 115 is removed, for example, by an oxygen plasma process or by dissolving in organic solvents.

Referring to FIG. 1K, the interface layer 114 is removed from the package structure 112 where exposed by the external leads 116. Copper in the interface layer 114 may be removed by a wet etch process using chloride ions, for example by having ferric chloride or ammonium chloride in the wet etch process. Titanium or tantalum in the interface layer 114 may be removed by a wet etch process using an aqueous acid mixture, such as mixture including nitric acid, phosphoric acid, or hydrochloric acid, in the wet etch process. Tungsten in the interface layer 114 may be removed by a wet etch process containing hydrogen peroxide. A sublayer of the interface layer 114 which includes more than 80 percent tungsten and a remainder or titanium may be removed using hydrogen peroxide alone. The interface layer 114, which is electrically conductive, remains in place between the pillars 105 and the external leads 116.

Referring to FIG. 1L, the microelectronic device 100 is singulated from the additional microelectronic devices 100a. A second singulation coating 118 may be applied to the package structure 112, covering the external leads 116, to protect the external leads 116 during a second singulation process. The package plate 111 may be mounted on a second singulation film 119 to hold the microelectronic device 100 and additional microelectronic devices 100a in place during the second singulation process. The microelectronic device 100 may be singulated from the package plate 111 by a saw process, a laser scribe process, an etching process, or other singulation process. After the second singulation process is completed, the second singulation coating 118 may be removed and the microelectronic device 100 and the additional microelectronic devices 100a may be demounted from the second singulation film 119.

FIG. 1M depicts the completed microelectronic device 100. The pillars 105, the external leads 116, and the interface layer 114 between the pillars 105 and the external leads 116 are parts of package leads 120 of the microelectronic device 100. The package structure 112 extends further from the component surface 104 than the pillar 105. The package leads 120 are advantageously free of a solder joint, and free of metals which may form intermetallic compounds with copper, such as tin, lead, indium, and bismuth. Thus, the microelectronic device 100 may be operated with higher current densities than comparable devices having solder joints in the package leads. The external leads 116 may be attached to a circuit board or chip carrier by a solder joint at connection surfaces 121 at an exterior of the microelectronic device 100. An area of each connection surface 121 is greater than an area of a top surface 122 of the corresponding pillar 105, so that a current density through the solder joint is lower than a current density through the pillar 105, which may reduce formation of intermetallic compounds proximate to the solder joint.

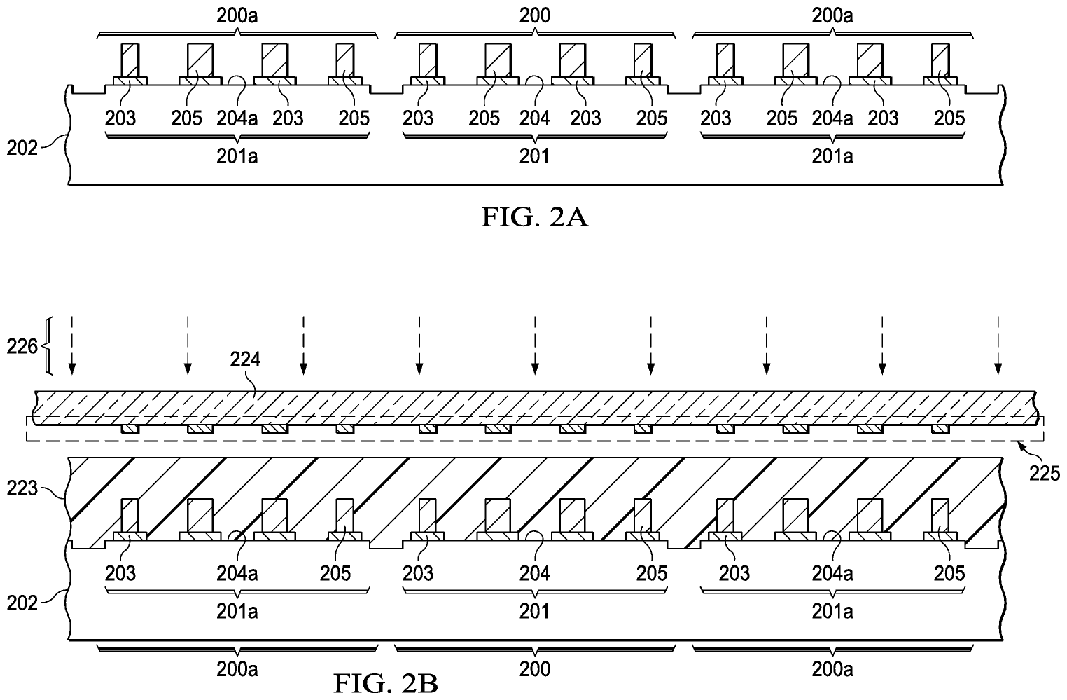

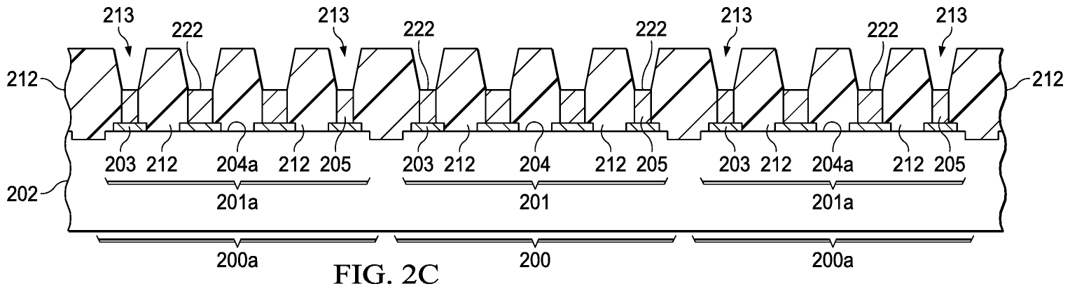

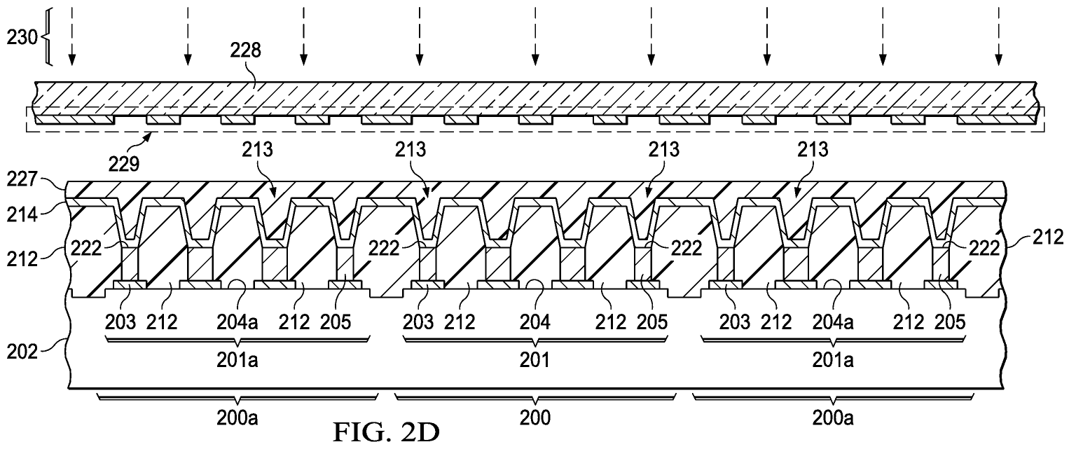

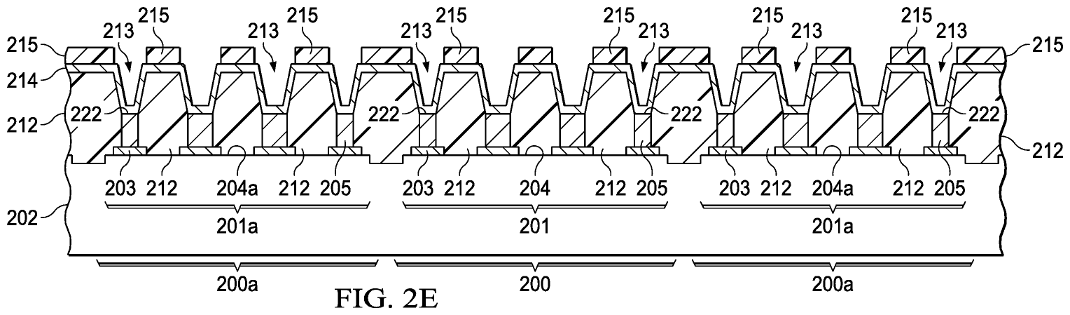

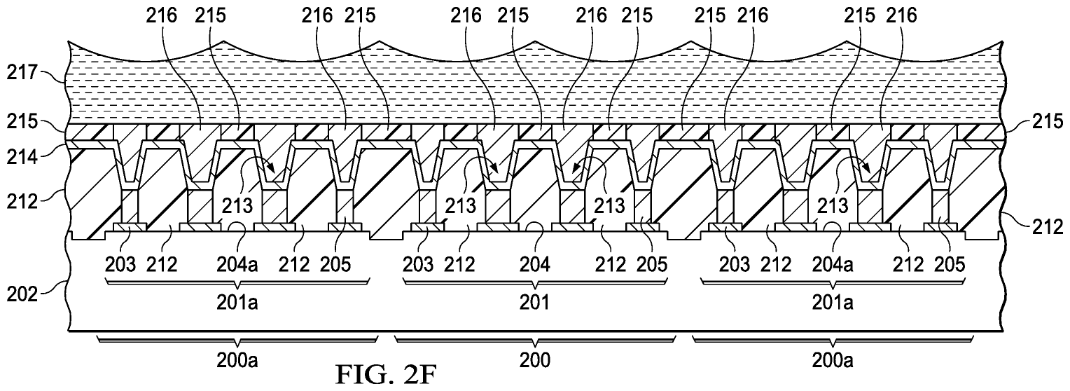

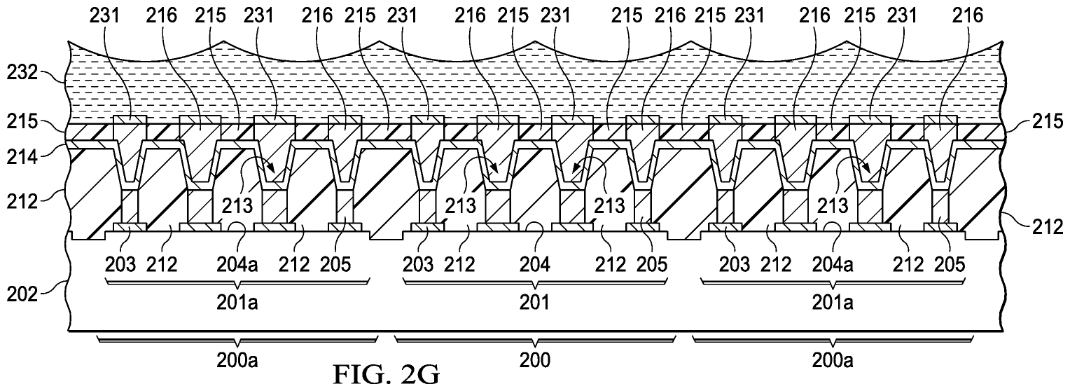

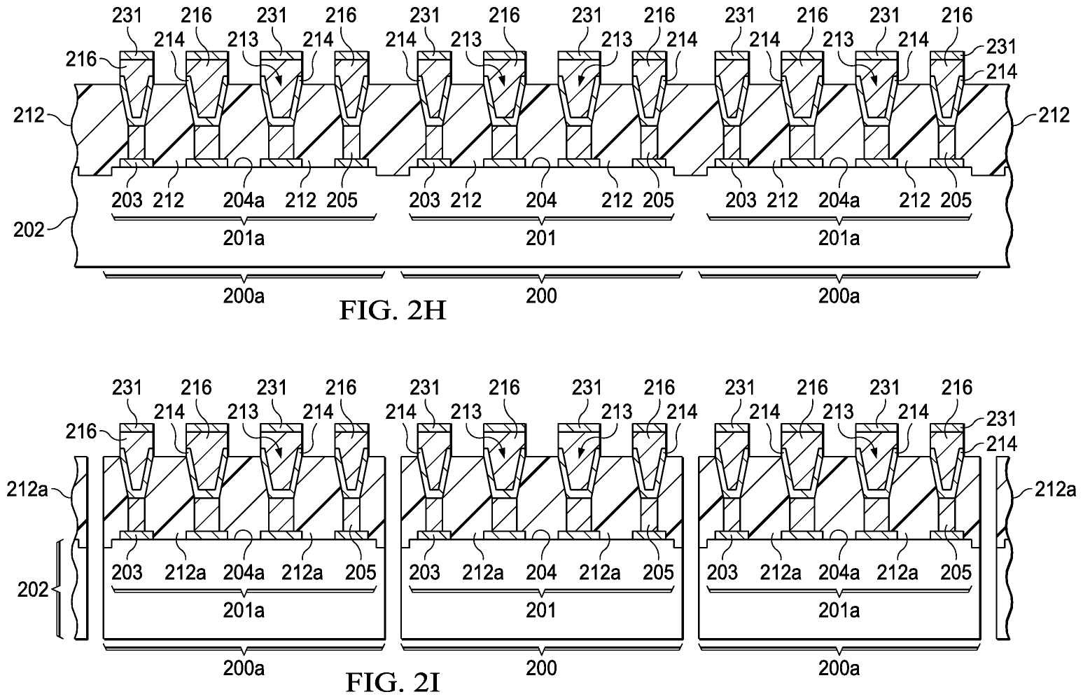

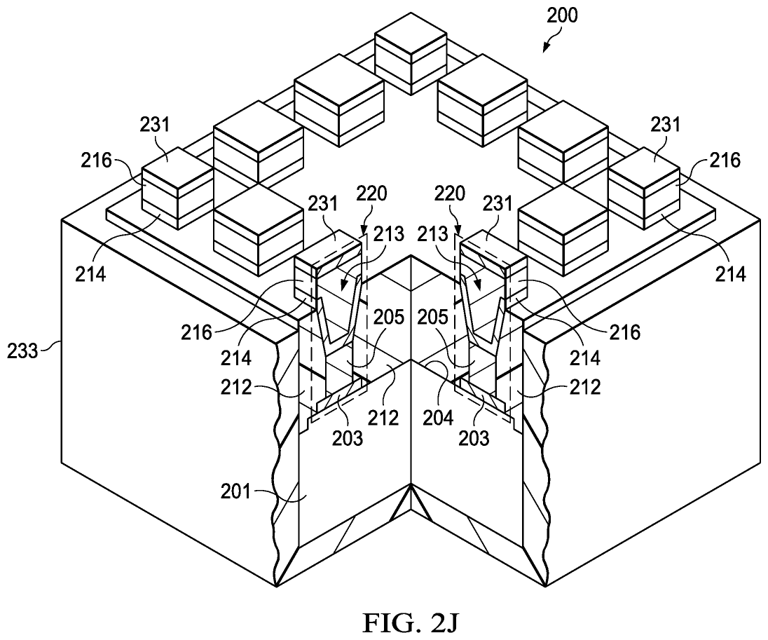

FIG. 2A through FIG. 2J are cross sections of another microelectronic device having a solder-free package lead, depicted in stages of another example method of formation. Referring to FIG. 2A, the microelectronic device 200 includes a die 201 which is part of a workpiece 202 containing additional die 201a of additional microelectronic devices 200a. The die 201 may be implemented as an integrated circuit, a discrete semiconductor device, a MEMS device, an electro-optical device, or a microfluidics device, for example. The workpiece 202 may be implemented as a semiconductor wafer, a MEMS substrate, or a microfluidics substrate, for example. The die 201 and the additional die 201a have terminals 203 at a component surface 204 of the die 201 and component surfaces 204a of the additional die 201a. The terminals 203 are electrically conductive, and may be implemented as bump bond pads or through-substrate vias, for example. Pillars 205 are disposed on the terminals 203. The pillars 205 may include primarily copper, or may include other metals, as disclosed in reference to the pillars 105 of FIG. 1A. The pillars 205 may also include interface layers, not shown in FIG. 2A, in direct contact with the terminals 203, as disclosed in reference to FIG. 1A.

Referring to FIG. 2B, a photosensitive polymer layer 223, such as photosensitive epoxy, is formed over the workpiece 202, covering the terminals 203 and the pillars 205. The photosensitive polymer layer 223 may be formed by a spin coat process, a spray process, or an additive material extrusion process, for example.

A first photomask 224 is placed over the photosensitive polymer layer 223. The first photomask 224 has a first pattern layer 225 which is configured to block light in areas corresponding to the pillars 205. The photosensitive polymer layer 223 is exposed with ultraviolet light 226 through the first photomask 224 in areas around the pillars 205; the ultraviolet light 226 is blocked by the first pattern layer 225 in areas over the pillars 205. Exposure to the ultraviolet light 226 causes crosslinking in the photosensitive polymer layer 223 in the areas around the pillars 205.

Referring to FIG. 2C, the photosensitive polymer layer 223 of FIG. 2B which was exposed by the ultraviolet light 226 of FIG. 2B provides a package structure 212. The photosensitive polymer layer 223 which was not exposed by the ultraviolet light 226 is removed by a develop operation to form access cavities 213 in the package structure 212 over the pillars 205. The develop operation may include dissolution of the photosensitive polymer layer 223 which was not exposed by the ultraviolet light 226 in an organic solvent. The cross-linked photosensitive polymer layer 223 which was exposed by the ultraviolet light 226 is less soluble in the organic solvent, and remains on the workpiece 202 to provide the package structure 212. Any organic residue, not shown in FIG. 2C, which remains on top surfaces 222 of the pillars 205 may be removed. The organic residue may be removed, for example, by an oxygen plasma process such as an ash process or a reactive ion etch (RIE) process.

Referring to FIG. 2D, an interface layer 214 is formed on the package structure 212, extending into the access cavities 213 and contacting the top surfaces 222 of the pillars 205. The interface layer 214 is electrically conductive. The interface layer 214 may include, for example, an adhesion sublayer contacting the package structure 212, and a plating seed sublayer on the adhesion sublayer, as disclosed in reference to the interface layer 114 of FIG. 1H.

A photoresist layer 227 is formed over the interface layer 214. The photoresist layer 227 may include a positive tone photoresist. The photoresist layer 227 may be formed by a spin coat process, or a spray process, for example.

A second photomask 228 is placed over the photoresist layer 227. The second photomask 228 has a second pattern layer 229 which is configured to transmit light in areas for subsequently-formed external leads 216, shown in FIG. 2F. The areas for the subsequently-formed external leads 216 include the access cavities 213. The second pattern layer 229 is configured to block light outside of the areas for the subsequently-formed external leads 216.

The photoresist layer 227 is exposed with ultraviolet light 230 through the second photomask 228 in the areas for the subsequently-formed external leads 216. Exposure to the ultraviolet light 230 causes formation of polar functional groups in the photoresist layer 227 which provides increased solubility of the photoresist layer 227 in an aqueous alkaline solution.

Referring to FIG. 2E, the photoresist layer 227 of FIG. 2D which was exposed with the ultraviolet light 230 of FIG. 2D is removed by a develop operation using the aqueous alkaline solution, not shown in FIG. 2E. The photoresist layer 227 which was not exposed with the ultraviolet light 230 remains on the interface layer 214 to provide an external lead mask 215. The external lead mask 215 exposes the interface layer 214 in the areas for the subsequently-formed external leads 216, shown in FIG. 2F. The external lead mask 215 exposes the interface layer 214 in the access cavities 213. The external lead mask 215 may have a thickness of 1 micron to 100 microns, for example, to provide a desired thickness of the external leads 216. Alternatively, the external lead mask 215 may include organic polymer material and may be formed by an additive process such as material jetting or material extrusion.

Referring to FIG. 2F, the external leads 216 are formed on the interface layer 214 where exposed by the external lead mask 215, by a first plating process using a first plating bath 217. The first plating process may be implemented as an electroplating process using the interface layer 214 as a cathode, or an electroless plating process. The first plating bath 217 may include copper, so that the external leads include primarily copper. The external leads 216 may include any of the materials disclosed in reference to the external leads 116 of FIG. 1J. The external leads 216 extend into the access cavities 213, so that the pillars 205 are coupled to the external leads 216 through the interface layer 214. After the external leads 216 are formed, the microelectronic device 200 is separated from the first plating bath 217.

Referring to FIG. 2G, barrier layers 231 may optionally be formed on the external leads 216 by a second plating process using a second plating bath 232. The barrier layers 231 may include one or more metals which reduce diffusion of copper from the external leads 216 into subsequently-formed solder joints, not shown in FIG. 2G, on the external leads 216, and reduce diffusion of tin from the solder joints into the external leads 216. Tin and copper may form intermetallic compounds which increase electrical resistances between the external leads 216 and the solder joints, and may degrade performance of the microelectronic device 200. Thus, the barrier layers 231 may improve a reliability of the microelectronic device 200. After the barrier layers 231 are formed, the microelectronic device 200 is separated from the second plating bath 232. The external lead mask 215 is subsequently removed, for example, by an oxygen plasma process or by dissolving in organic solvents.

Referring to FIG. 2H, the interface layer 214 is removed from the package structure 212 where exposed by the external leads 216. Copper, titanium, tantalum, or tungsten in the interface layer 214 may be removed as disclosed in reference to FIG. 1K. The interface layer 214, which is electrically conductive, remains in place between the pillars 205 and the external leads 216.

Referring to FIG. 2I, the die 201 is singulated from the workpiece 202 by a singulation process. The singulation process also separates the package structure 212 of the microelectronic device 200 from corresponding package structures 212a of the additional microelectronic device 200a. The singulation process may include one or more saw or scribe processes, for example.

Referring to FIG. 2J, a package coating 233 may optionally be formed on exposed surfaces of the die 201. The package coating 233 may be optically opaque, and may be electrically non-conductive, to electrically and optically isolate the die 201. The pillars 205, the external leads 216, and the interface layer 214 between the pillars 205 and the external leads 216 are parts of package leads 220 of the microelectronic device 200. The package structure 212 extends further from the component surface 204 than the pillar 205. The package leads 220 are advantageously free of a solder joint, and free of metals which may form intermetallic compounds with copper, accruing the advantages disclosed in reference to FIG. 1M.

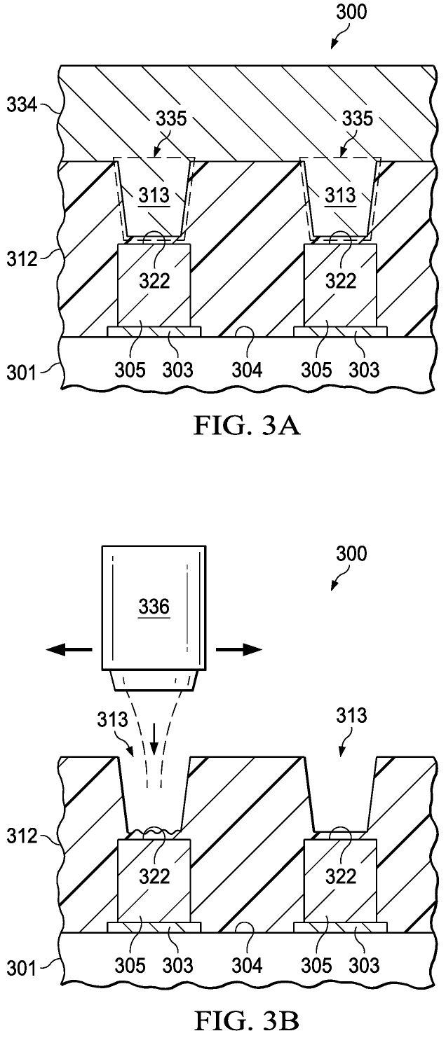

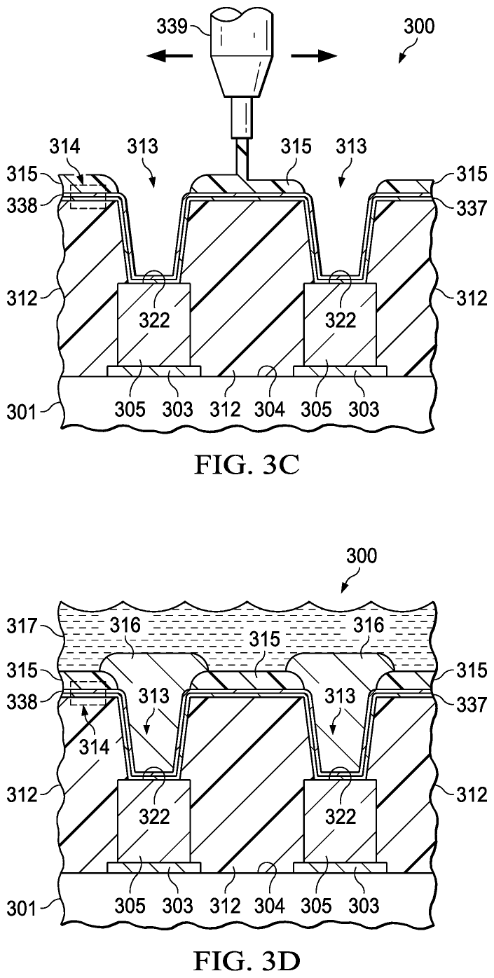

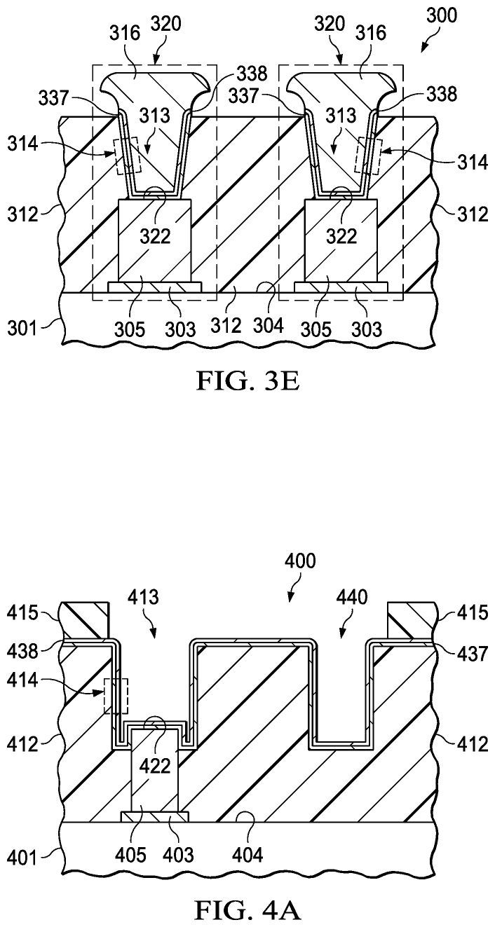

FIG. 3A through FIG. 3E are cross sections of a microelectronic device having a solder-free package lead, depicted in stages of a further example method of formation. Referring to FIG. 3A, the microelectronic device 300 includes a die 301 having a component surface 304. The die 301 has terminals 303 at the component surface 304, and pillars 305 disposed on the terminals 303. The terminals 303 and the pillars 305 are electrically conductive.

A package structure 312 is formed on the die 301, covering the pillars 305 and the component surface 304. The package structure 312 of this example is formed by an injection molding process using a mold plate 334. The mold plate 334 has access extensions 335 which form access cavities 313 in the package structure 312 over the pillars 305. The access extensions 335 may be separated from top surfaces 322 of the pillars 305 by a portion of the package structure 312, as depicted in FIG. 3A, to reduce damage to the pillars 305 and the underlying portions of the die 301. The package structure 312 is electrically non-conductive, and may include polymer material suitable for injection molding, such as epoxy. The mold plate 334 is subsequently removed. Forming the access cavities 313 using the access extensions 335 of the mold plate 334 may advantageously reduce fabrication cost and complexity for the microelectronic device 300 compared to removing material from the package structure 312 by other means.

Referring to FIG. 3B, material of the package structure 312 in the access cavities 313 on the top surfaces 322 of the pillars 305 is removed to expose at least portions of the top surfaces 322. The material of the package structure 312 may be removed by a laser ablation process using a laser apparatus 336, as depicted in FIG. 3B. Alternatively, the material of the package structure 312 may be removed by another method, such as an oxygen plasma process or an oxygen RIE process. FIG. 3B depicts removal of the material of the package structure 312 on the top surfaces 322 of the pillars 305 partway to completion. After the removal of the material of the package structure 312 on the top surfaces 322 of the pillars 305 is completed, the access cavities 313 expose the top surfaces 322 of the pillars 305.

Referring to FIG. 3C, an interface layer 314 is formed on the package structure 312, extending into the access cavities 313 and contacting the pillars 305. The interface layer 314 is electrically conductive. The interface layer 314 of this example includes an adhesion sublayer 337 contacting the package structure 312 and the pillars 305. The adhesion sublayer 337 may include metals that exhibit strong adhesion to the package structure 312, such as titanium, tantalum, or tungsten. The interface layer 314 of this example also includes a plating seed sublayer 338 over the adhesion sublayer 337. The plating seed sublayer 338 may include copper to facilitate a subsequent plating process. The adhesion sublayer 337 and the plating seed sublayer 338 may be formed by sputter processes, MOCVD processes, evaporation processes, or other thin film processes.

An external lead mask 315 is formed on the interface layer 314, exposing the interface layer 314 in areas for subsequently-formed external leads 316, shown in FIG. 3D. The external lead mask 315 exposes the interface layer 314 in the access cavities 313. The external lead mask 315 may include organic polymer material and may be formed by an additive process such as material extrusion using a material extrusion apparatus 339, as depicted in FIG. 3C. Other methods of forming the external lead mask 315, such as photolithographic processes, are within the scope of this example.

Referring to FIG. 3D, the external leads 316 are formed on the interface layer 314 where exposed by the external lead mask 315. The external leads 316 are formed by a plating process using a plating bath 317. The plating process may be an electroplating process in which a cathode is electrically coupled to the plating seed sublayer 338. The external leads 316 extend into the access cavities 313, so that the pillars 305 are coupled to the external leads 316 through the interface layer 314. The external leads 316 may extend above the top surface of the external lead mask 315, as depicted in FIG. 3D. After the external leads 316 are formed, the microelectronic device 300 is separated from the plating bath 317. The external lead mask 315 is subsequently removed.

Referring to FIG. 3E, the interface layer 314 is removed from the package structure 312 where exposed by the external leads 316. The plating seed sublayer 338 may be removed by a wet etch process using an aqueous acid mixture. The adhesion sublayer 337 may be removed by a wet etch process using an aqueous acid mixture containing nitric acid, or by a wet etch process containing hydrogen peroxide. Other processes for removing the interface layer 314 are within the scope of this example.

The pillars 305, the external leads 316, and the interface layer 314 between the pillars 305 and the external leads 316 are parts of package leads 320 of the microelectronic device 300. The package leads 320 are advantageously free of a solder joint, and free of metals which may form intermetallic compounds, accruing the advantages disclosed in reference to FIG. 1M.

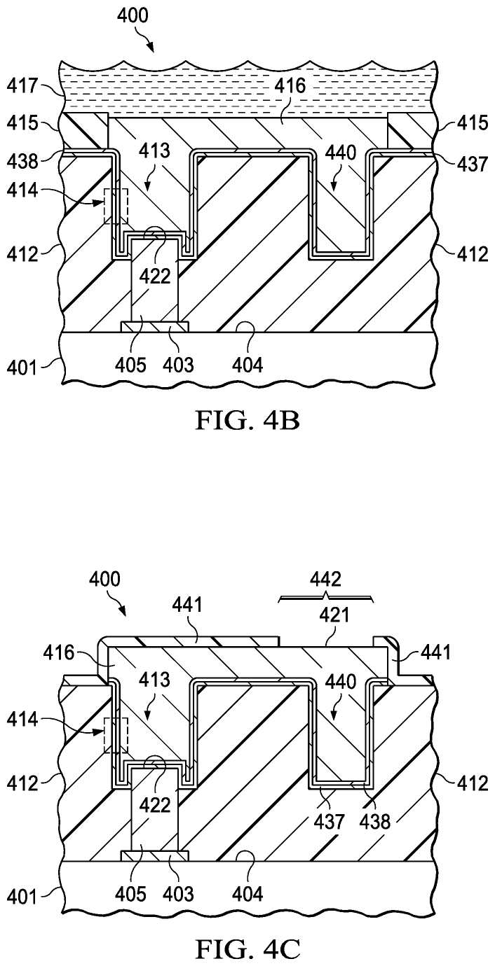

FIG. 4A through FIG. 4C are cross sections of a microelectronic device having a solder-free package lead, depicted in stages of another example method of formation. Referring to FIG. 4A, the microelectronic device 400 includes a die 401 having a component surface 404. The die 401 has a terminal 403 at the component surface 404, and a pillar 405 disposed on the terminal 403. The terminal 403 and the pillar 405 are electrically conductive.

A package structure 412 is disposed on the die 401. The package structure 412 contacts the pillar 405 and the component surface 404 of the die 401. The package structure 412 has an access cavity 413 which extends to a top surface 422 of the pillar 405. The package structure 412 has an anchor cavity 440 adjacent to the access cavity 413. The anchor cavity 440 may have different dimensions than the access cavity 413, that is, the anchor cavity 440 may have a different depth or width than the access cavity 413.

An interface layer 414 is formed on the package structure 412, extending into the access cavity 413 and contacting the pillar 405, and extending into the anchor cavity 440. The interface layer 414 is electrically conductive. The interface layer 414 of this example includes an adhesion sublayer 437 contacting the package structure 412 and the pillars 405, and a plating seed sublayer 438 over the adhesion sublayer 437. The adhesion sublayer 437 and the plating seed sublayer 438 may have compositions similar to, and may be formed by processes similar to, those disclosed in reference to the adhesion sublayer 337 and the plating seed sublayer 338 of FIG. 3C.

An external lead mask 415 is formed on the interface layer 414, exposing the interface layer 414 in an area for a subsequently-formed external lead 416, shown in FIG. 4C. The external lead mask 415 exposes the interface layer 414 in the access cavity 413 and in the anchor cavity 440, and exposes the interface layer 414 in a continuous region from the access cavity 413 to the anchor cavity 440. The external lead mask 415 may include photoresist or other polymer material, and may be formed by a photolithographic process or by an additive process.

Referring to FIG. 4B, the external lead 416 is formed on the interface layer 414 where exposed by the external lead mask 415. The external lead 416 is formed by a plating process using a plating bath 417. The external lead 416 extends into the access cavity 413 and into the anchor cavity 440, and on the interface layer 414 from the access cavity 413 to the anchor cavity 440. The pillar 405 is coupled to the external lead 416 through the interface layer 414 in the access cavity 413. After the external lead 416 is formed, the microelectronic device 400 is separated from the plating bath 417. The external lead mask 415 is subsequently removed.

Referring to FIG. 4C, the interface layer 414 is removed from the package structure 412 where exposed by the external lead 416. The plating seed sublayer 438 and the adhesion sublayer 437 may be removed by wet etch processes.

An optional solder mask 441 may be formed over the external lead 416, exposing a portion of a connection surface 421 of the external lead 416 in a solder pad area 442 that is laterally separated from the pillar 405. Thus, the external lead 416 may provide an effective redistribution functionality for the microelectronic device 400. Having the external lead 416 extend into the anchor cavity 440 may provide greater adhesion of the external lead 416 to the package structure 412 under the solder pad area 442 than would be attained without the anchor cavity 440. For the purposes of this disclosure, the terms “lateral” and “laterally” are understood to refer to a direction parallel to the component surface 404 of the die 401, and correspondingly so for other examples herein.

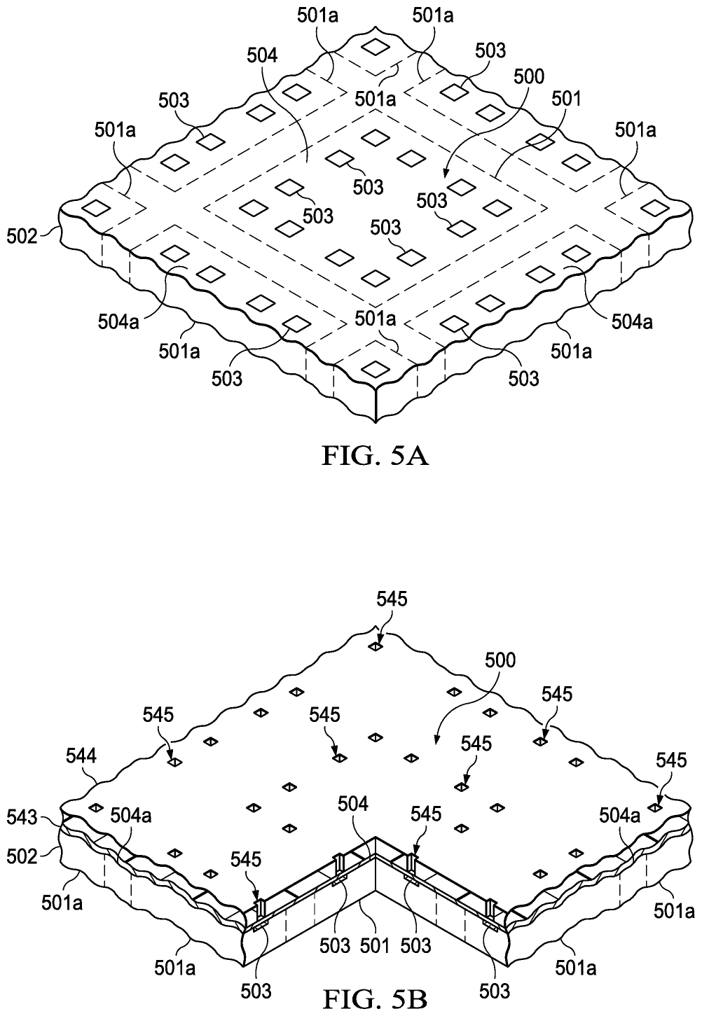

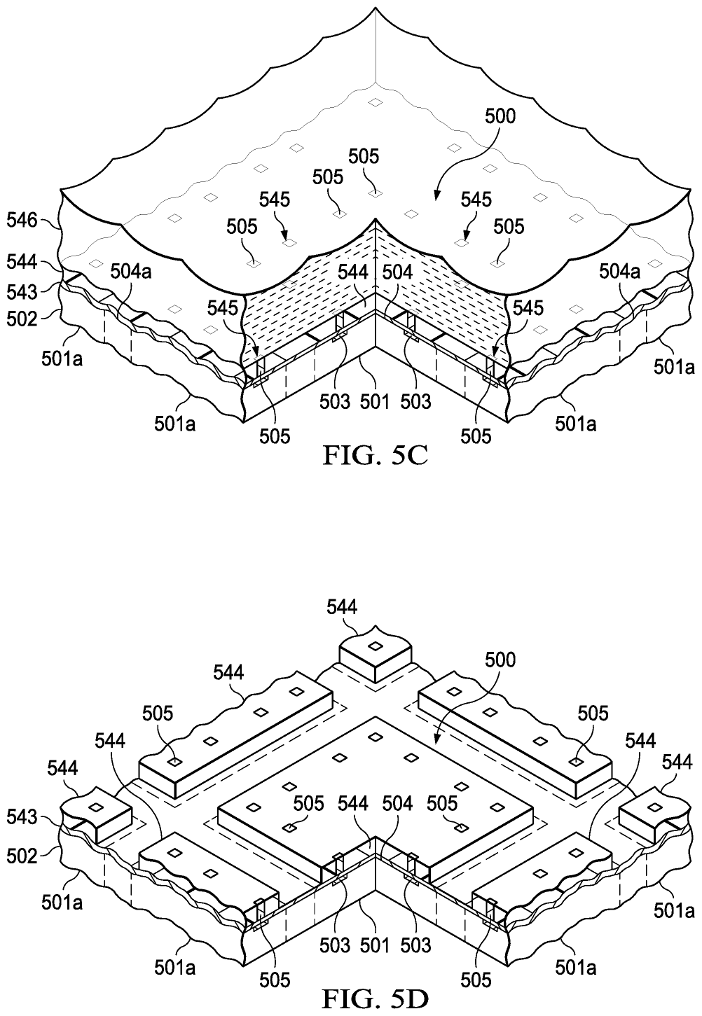

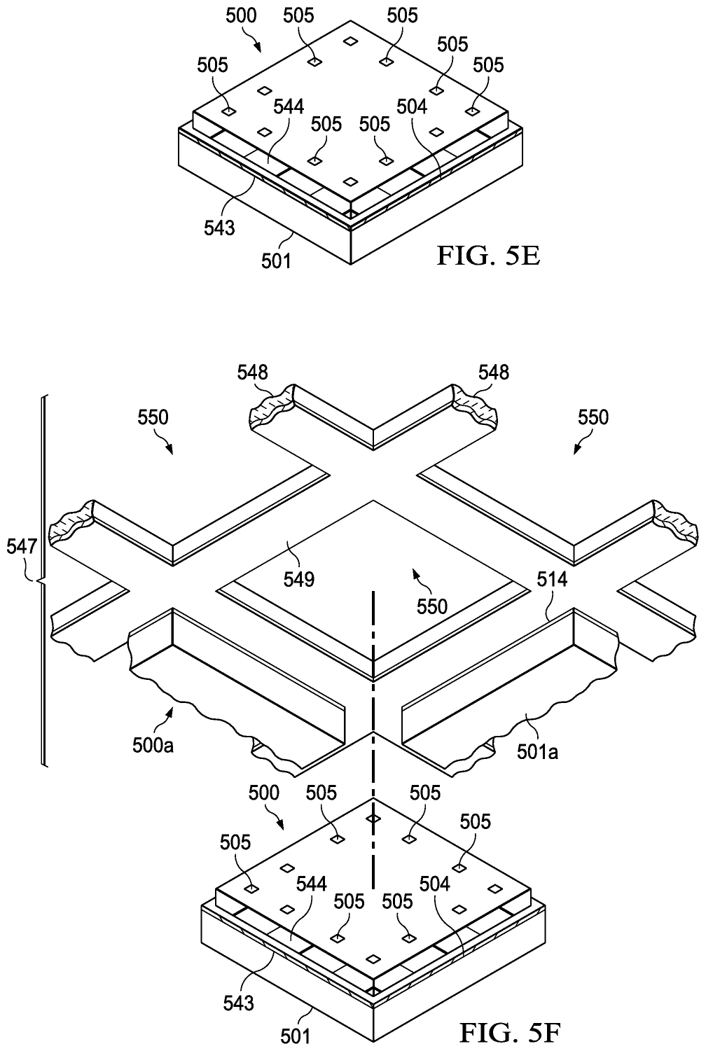

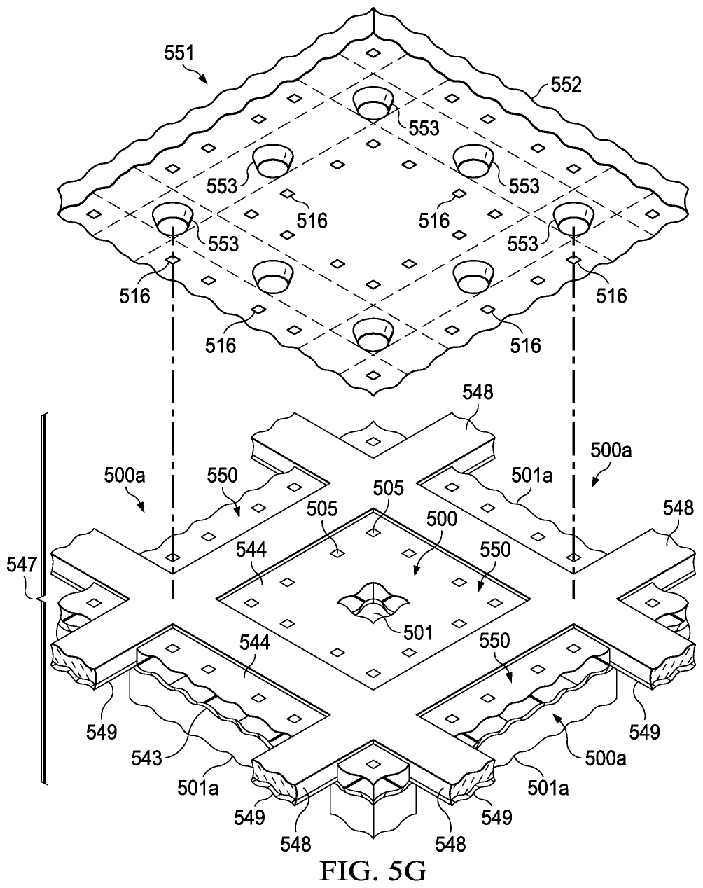

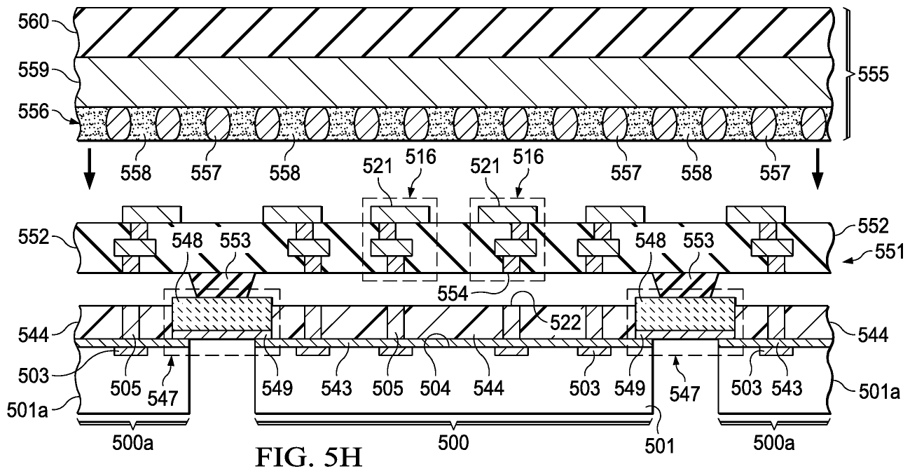

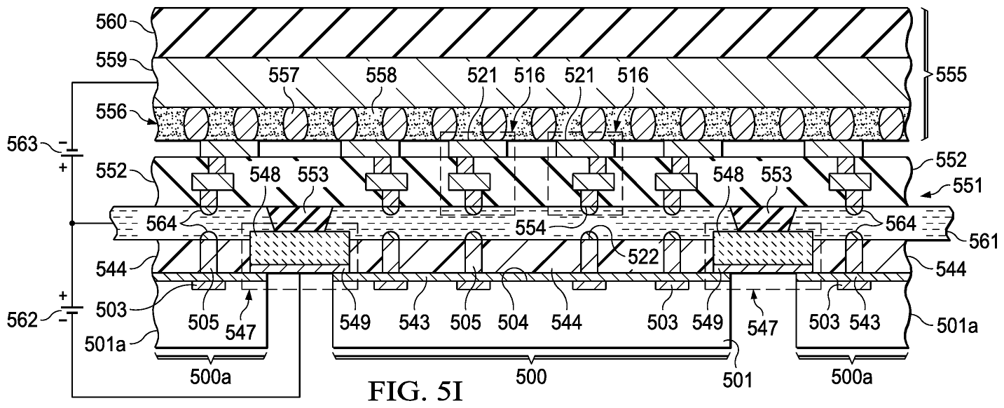

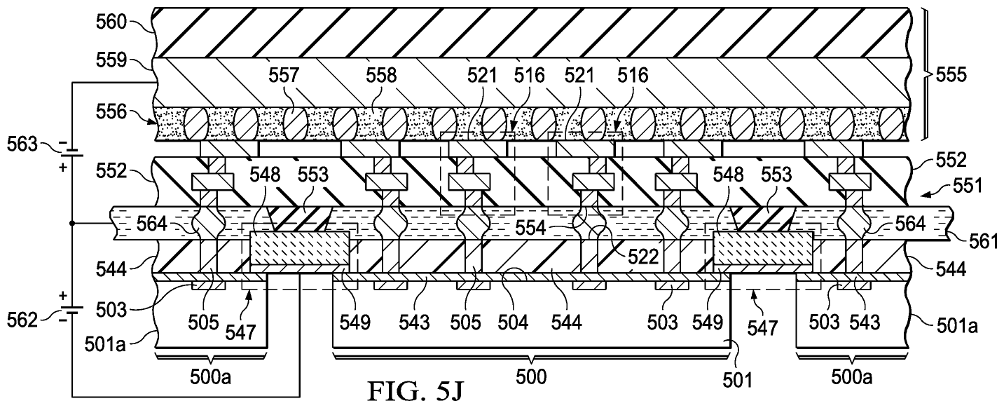

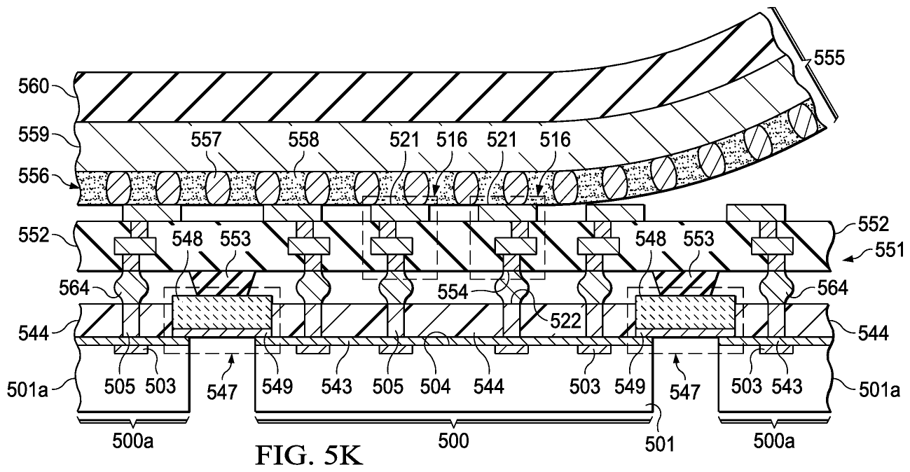

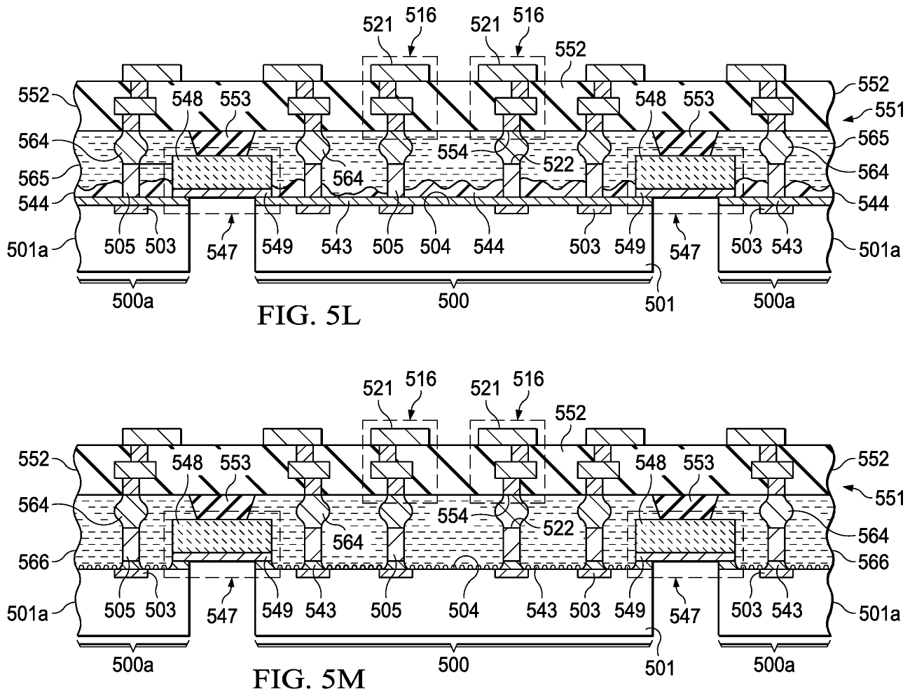

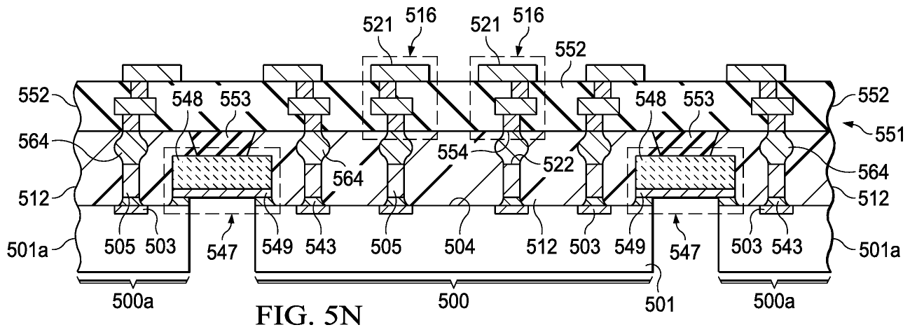

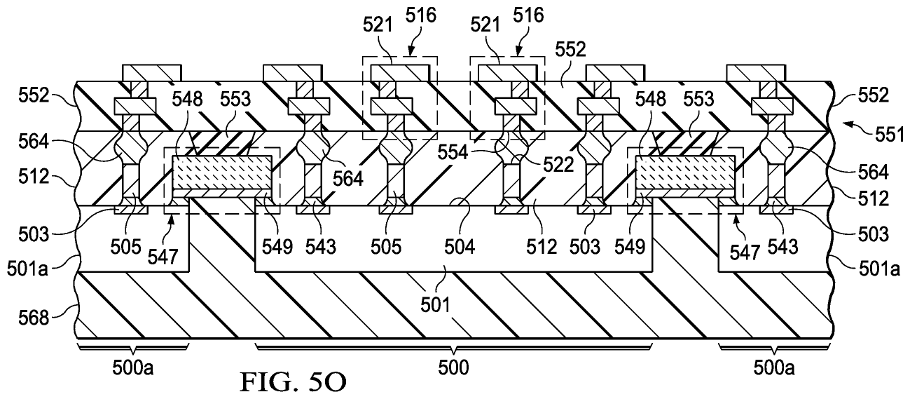

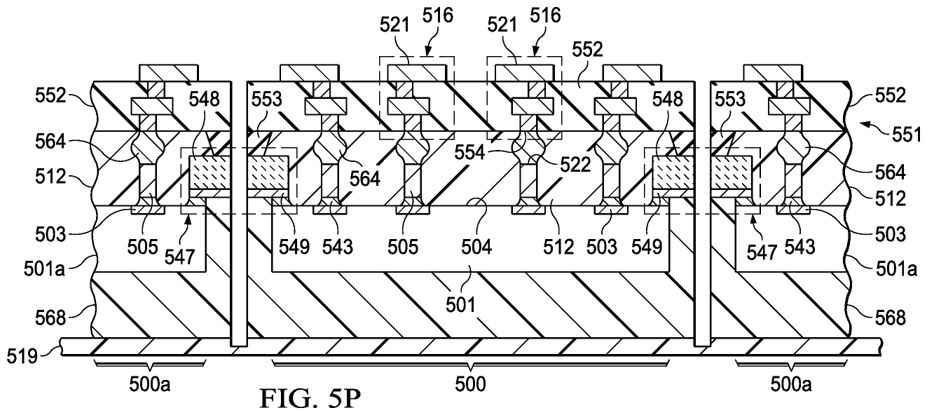

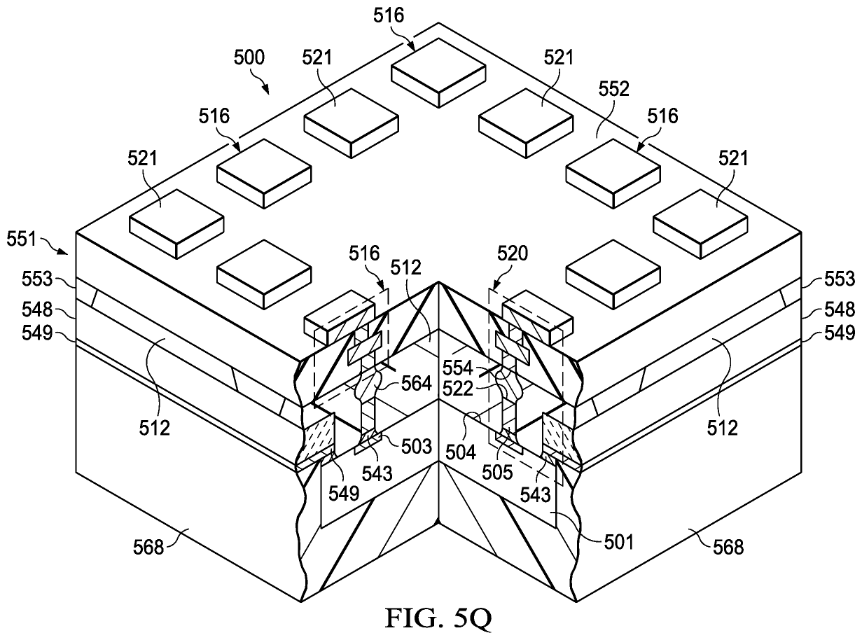

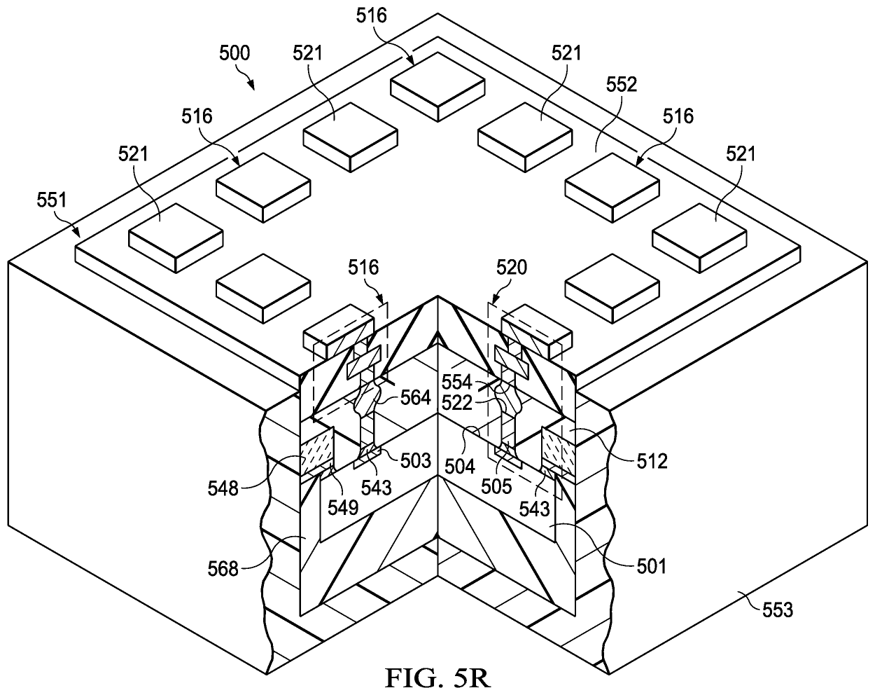

FIG. 5A through FIG. 5R are cross sections of a microelectronic device having a solder-free package lead, depicted in stages of a further example method of formation. Referring to FIG. 5A, the microelectronic device 500 includes a die 501 which is part of a workpiece 502 containing additional die 501a. The die 501 and the workpiece 502 may be implemented as any of the examples disclosed in reference to the die 101 and the workpiece 102 of FIG. 1A. The die 501 and the additional die 501a have terminals 503 at a component surface 504 of the die 501 and component surfaces 504a of the additional die 501a. The terminals 503 are electrically conductive.

Referring to FIG. 5B, a interface layer 543 is formed on the component surface 504 of the die 501, and on the component surfaces 504a of the additional die 501a. The interface layer 543 is electrically conductive, and directly contacts the terminals 503. The interface layer 543 may include, for example, an adhesion sublayer contacting the component surfaces 504 and 504a and the terminals 503, a barrier sublayer on the adhesion sublayer, and a plating seed sublayer on the first sublayer. The adhesion sublayer may include titanium, tantalum, or tungsten to provide adhesion to the component surfaces 504 and 504a. The barrier sublayer may include metals such as nickel, cobalt, molybdenum, titanium nitride, or tantalum nitride, which reduce diffusion of copper into the die 501 and 501a from subsequently-formed pillars 505, shown in FIG. 5C. The plating seed sublayer may include copper or gold to facilitate a subsequent plating process for forming the pillars 505.

A pillar mask 544 is formed over the interface layer 543. The pillar mask 544 has pillar holes 545 which extend through the pillar mask 544 and expose the interface layer 543 over the terminals 503. The pillar mask 544 may include a positive tone photoresist and may be formed by a photolithographic process. Alternatively, the pillar mask 544 may include organic polymer and may be formed by an additive process, such as a material extrusion process or a material jetting process. The pillar mask 544 may be 1 micron to 100 microns thick, for example.

Referring to FIG. 5C, pillars 505 are formed on the interface layer 543 in the pillar holes 545 of the pillar mask 544 by a pillar plating process using a pillar plating bath 546. The pillar plating process may be implemented as an electroplating process using the interface layer 543 as a cathode. The pillars 505 may include primarily copper, that is, more than 50 weight percent copper, to provide low electrical resistance in the pillars 505 and low fabrication costs for the microelectronic device 500. The pillars 505 may include some gold, nickel, cobalt, platinum, or any platable metal-rich electrically conductive metal. The pillars 505 are electrically conductive and make electrical contact to the interface layer 543. The pillars 505 of this example may have widths of 2 to 50 microns. FIG. 5C depicts the pillars 505 having equal widths. In an alternate version of this example, the pillars 505 may have different widths, to accommodate different currents during operation of the microelectronic device 500. The pillars 505 of this example extend proximate to a top surface of the pillar mask 544, within a vertical distance equal to the width of the pillars 505. After the pillars 505 are formed, the microelectronic device 500 is removed from the pillar plating bath 546. The pillar mask 544 is left in place for subsequent fabrication steps.

Referring to FIG. 5D, the pillar mask 544 is patterned to expose the interface layer 543 between the die 501 and adjacent instances of the additional die 501a. The pillar mask 544 may be patterned by exposing the positive tone photoresist in the pillar mask 544 in areas between the die 501 and adjacent instances of the additional die 501a, followed by a develop operation which removes the exposed positive tone photoresist. Other methods of patterning the pillar mask 544, such as laser ablation, are within the scope of this example. The pillar mask 544 is patterned so that the pillars 505 remain laterally surrounded by the pillar mask 544. Organic residue on the interface layer 543 between the die 501 and adjacent instances of the additional die 501a may be removed by an oxygen plasma process such as an asher process or an oxygen RIE process.

Referring to FIG. 5E, the die 501 is singulated from the workpiece 502 of FIG. 5D. The die 501 may be singulated by a saw process, a scribe process, or an etch process, for example. The die 501 is singulated so that a portion of the interface layer 543 is exposed by the pillar mask 544 around a perimeter of the die 501. The additional die 501a of FIG. 5D may be similarly singulated.

Referring to FIG. 5F, a plating frame 547 is provided. The plating frame 547 has a support lattice 548 and a plating bus 549 on the support lattice 548. The support lattice 548 is electrically non-conductive, and has die apertures 550 to accept the die 501 and the additional die 501a. The plating bus 549 is disposed on a face of the plating frame 547 so as to contact the interface layer 543 that is exposed around the perimeters of the die 501 and the additional die 501a.

The microelectronic device 500 is inserted into one of the die apertures 550, so that the interface layer 543 that is exposed around the perimeter of the die 501 makes an electrical connection to the plating bus 549. Instances of the additional microelectronic devices 500a are inserted into remaining instances of the die apertures 550, as indicated in FIG. 5F.

FIG. 5G depicts a portion of the plating frame 547 after the die apertures 550 are filled with the die 501 and the additional die 501a. The pillars 505 are exposed in the die apertures 550. A backing plate, not shown in FIG. 5G, may be applied to the die 501 and the additional die 501a to hold the interface layer 543 against the plating bus 549 to provide a consistent electrical connection. Other structures for holding the interface layer 543 against the plating bus 549 are within the scope of this example.

An external lead lamina 551 is provided. The external lead lamina 551 includes a dielectric lamination stack 552 and external leads 516 which extend through the dielectric lamination stack 552. The dielectric lamination stack 552 is electrically non-conductive, and may include epoxy, polyester, or silicone, for example, and may be reinforced with fiberglass. The external leads 516 are electrically conductive, and may include primarily copper, that is, more than 50 weight percent copper, or may include primarily other electrically conductive material. The external lead lamina 551 includes spacers 553 to provide a desired separation between the external leads 516 and the pillars 505. The external lead lamina 551 is aligned with the die 501 and the additional die 501a in the plating frame 547 and brought into contact with the support lattice 548 of the plating frame 547.

FIG. 5H is a cross section of the external lead lamina 551 in contact with the plating frame 547. The external leads 516 have connection surfaces 521 at an exterior of the microelectronic device 500 and the additional microelectronic devices 500a, and have plating surfaces 554 at an interior surface of the external lead lamina 551, located opposite from the exterior surface. The external leads 516 may be implemented as multi-level leads with the connection surfaces 521 being laterally offset from the plating surfaces 554, as depicted in FIG. 5H. Alternatively, the external leads 516 may be implemented as through vias that extend straight through the dielectric lamination stack 552. The plating surfaces 554 are aligned with, and proximate to, top surfaces 522 of the pillars 505, as depicted in FIG. 5H.

A cathode bus 555 is brought into contact with the connection surfaces 521 of the external leads 516. The cathode bus 555 may include an anisotropic conductive tape 556 with metal particles 558 extending through a double-sided adhesive tape 559, a metal sheet 560 attached to the anisotropic conductive tape 556 and making electrical contacts to the metal particles 558, and an insulator sheet attached to the metal sheet 560. Other implementations of the cathode bus 555 are within the scope of this example.

Referring to FIG. 5I, a plating solution 561 is introduced between the external lead lamina 551 and the die 501 and the additional die 501a in the plating frame 547. The plating solution 561 contacts the top surfaces 522 of the pillars 505 and the plating surfaces 554 of the external leads 516. The plating solution 561 includes metal ions, such as copper ions, for electroplating. A first plating bias 562 is applied between the plating solution 561 and the pillars 505, through the plating bus 549 of the plating frame 547. A second plating bias 563 is applied between the plating solution 561 and the external leads 516 through the cathode bus 555. The first plating bias 562 and the second plating bias 563 may be applied by power supplies of an electroplating apparatus, represented schematically in FIG. 5I as voltage sources 562 and 563.

As part of a metal joint plating process, current flows through the plating solution 561 and through the top surfaces 522 into the pillars 505, as a result of the first plating bias 562 being applied, forming portions of plated metal joints 564 between the pillars 505 and the external leads 516. As part of the metal joint plating process, current also flows through the plating solution 561 and through the plating surfaces 554 into the external leads 516, as a result of the second plating bias 563 being applied, forming additional portions of plated metal joints 564 between the pillars 505 and the external leads 516. During the metal joint plating process, the top surfaces 522 of the pillars 505 may be separated from the plating surfaces 554 of the external leads 516 by a distance less than 5 times an average width of the top surfaces 522 of the pillars 505 and the plating surfaces 554 of the external leads 516. Shapes of the plated metal joints 564 may be difficult to control if the top surfaces 522 of the pillars 505 are separated from the plating surfaces 554 of the external leads 516 by a distance greater than 5 times an average width. FIG. 5I depicts the plated metal joints 564 partway to complete formation. The plating solution 561 may include additives, such as organic sulfides, disulfides, thioethers, and thiocarbonates, together with quaternary nitrogen compounds, to reduce lateral expansion of the plated metal joints 564 and thus prevent electrical shorting between adjacent instances of the plated metal joints 564.

Referring to FIG. 5J, the metal joint plating process is continued until the plated metal joints 564 are completely formed, so that each of the pillars 505 are electrically connected through an instance of the plated metal joints 564 to a corresponding instance of the external leads 516. Depending on the additives in the plating solution 561, the plated metal joints 564 may have expanded center portions, as depicted in FIG. 5J, or may have other shapes. The metal joint plating process is terminated before the plated metal joints 564 contact adjacent instances of the plated metal joints 564, possibly causing undesirable short circuits. The plating solution 561 is removed after the plated metal joints 564 are completely formed.

Referring to FIG. 5K, the cathode bus 555 is removed. The cathode bus 555 may be removed by peeling the anisotropic conductive tape 556 from the external leads 516, as indicated in FIG. 5K. Removal of the cathode bus 555 may be assisted by an organic solvent such as a citrus solvent which partially dissolves an adhesive in the double-sided adhesive tape 559.

Referring to FIG. 5L, the pillar mask 544 is removed. FIG. 5L depicts removal of the pillar mask 544 partway to completion. The pillar mask 544 may be removed by dissolving in an organic solvent 565, followed by a wet clean process using an aqueous mixture of ammonium hydroxide and hydrogen peroxide, for example. Other methods for removing the pillar mask 544 are within the scope of this example.

Referring to FIG. 5M, the interface layer 543 is removed where exposed by the pillars 505. Copper in the interface layer 543 may be removed by an aqueous ferric chloride solution 566. Tungsten in the interface layer 543 may be removed by an aqueous solution of hydrogen peroxide. Titanium or tantalum in the interface layer 543 may be removed by an etchant mixture including nitric acid. Other methods for removing the interface layer 543 are within the scope of this example. FIG. 5M depicts removal of the interface layer 543 partway to completion.

Referring to FIG. 5N, a package structure 512 is formed between the external lead lamina 551 and the die 501 and the additional die 501a in the plating frame 547. The package structure 512 is electrically non-conductive, and may include, for example, epoxy, BCB, silicone, polyurethane, or polyester. Other non-conductive material for the package structure 512 is within the scope of this example. The package structure 512 may be formed by injection molding, reaction injection molding, or other process.

Referring to FIG. 5O, an overmold structure 568 is formed on the die 501 and the additional die 501a, and on the plating frame 547 between the die 501 and the additional die 501a. The overmold structure 568 is electrically non-conductive, and may cover the die 501 and the additional die 501a. The overmold structure 568 may include, for example, epoxy, BCB, or silicone, and may be formed by injection molding, slump molding, spin coating, spraying, additive extrusion, material jetting, or other process.

Referring to FIG. 5P, the microelectronic device 500 is singulated from the additional microelectronic devices 500a by a singulation process, such as a saw process. The microelectronic device 500 and the additional microelectronic devices 500a may be mounted on a singulation film 519 during the singulation process. After the singulation process is completed, the microelectronic device 500 and the additional microelectronic devices 500a may be demounted from the singulation film 519.

FIG. 5Q depicts the microelectronic device 500 after the singulation process. In this example, the plating bus 549 may extend to a lateral perimeter around the microelectronic device 500.

Referring to FIG. 5R, a package coating 533 may optionally be formed on exposed surfaces of the plating bus 549. The package coating 533 may be electrically non-conductive, to electrically and optically isolate the plating bus 549. The pillars 505, the interface layer 543 between the pillars 505 and the terminals 503, the external leads 516, and the plated metal joint 564 between the pillars 505 and the external leads 516, are parts of package leads 520 of the microelectronic device 500. The package structure 512 extends further from the component surface 504 than the pillar 505. The package leads 520 are advantageously free of a solder joint, and free of metals which may form intermetallic compounds with copper, accruing the advantages disclosed in reference to FIG. 1M.

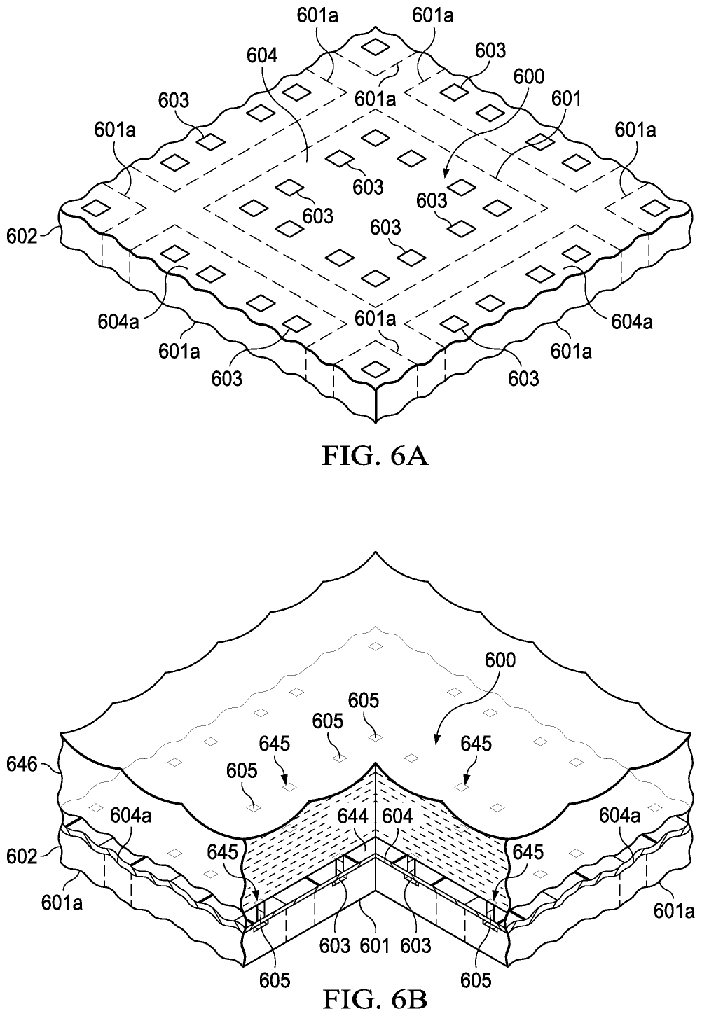

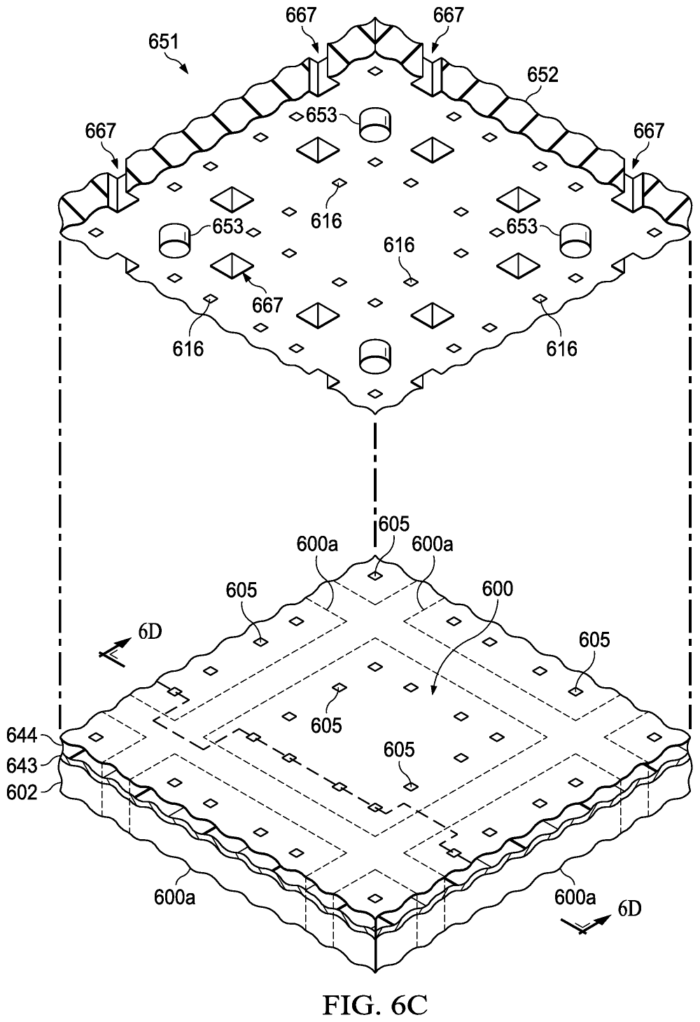

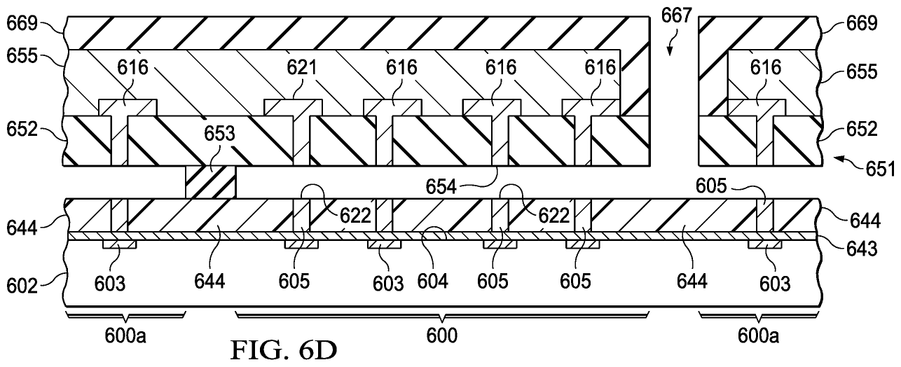

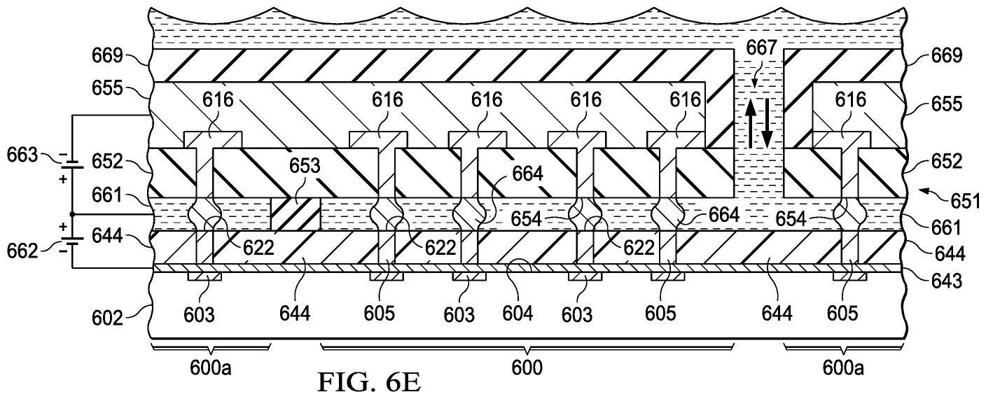

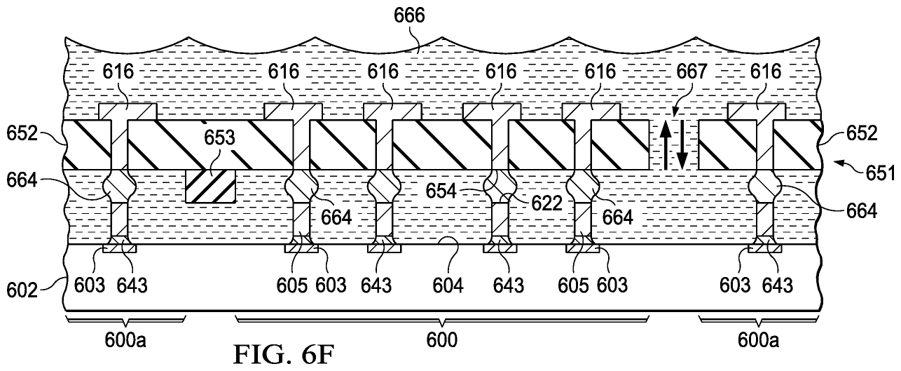

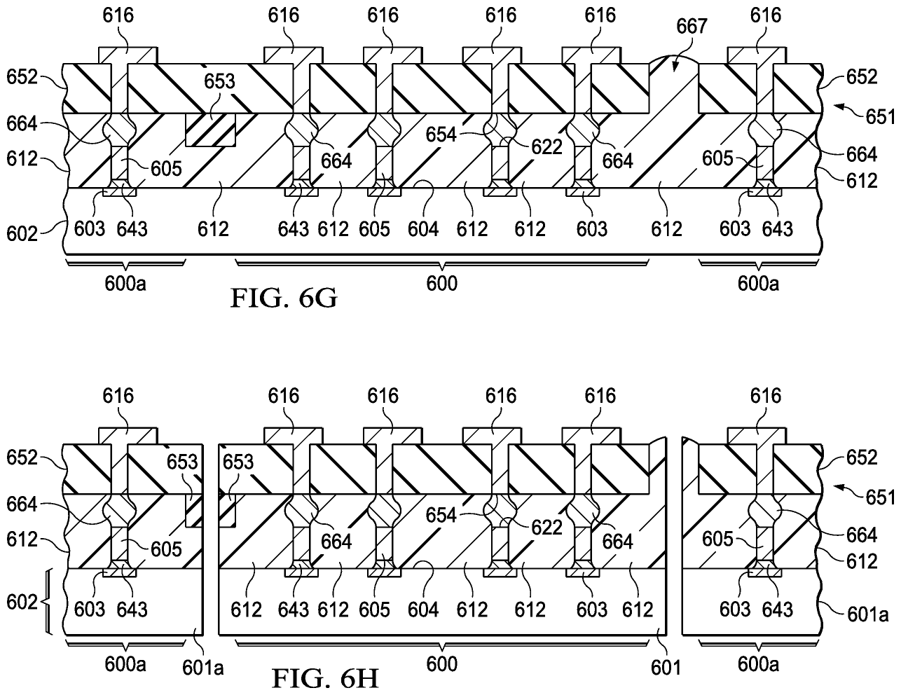

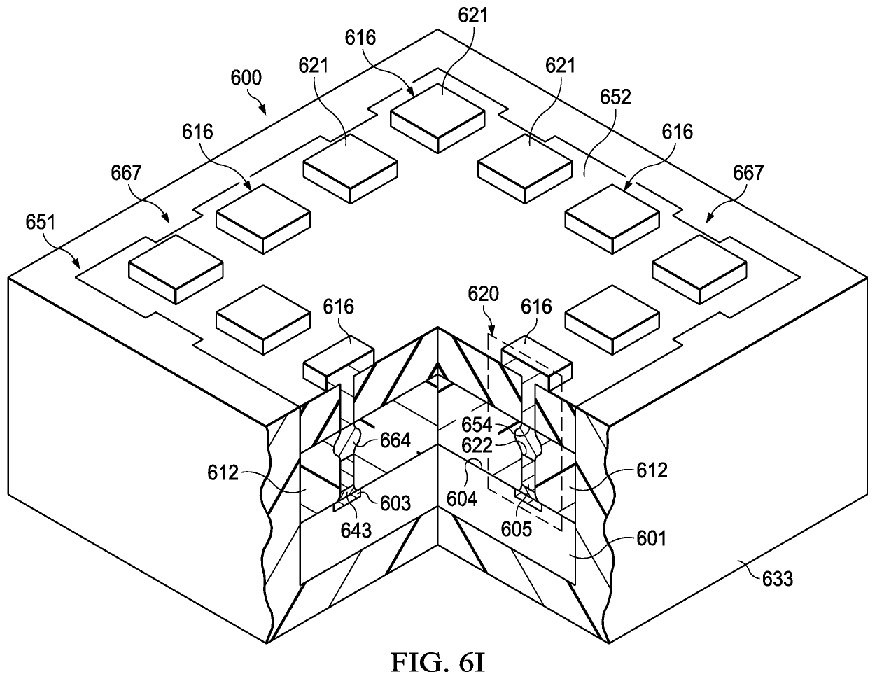

FIG. 6A through FIG. 6I are cross sections of a microelectronic device having a solder-free package lead, depicted in stages of another example method of formation. Referring to FIG. 6A, the microelectronic device 600 includes a die 601 which is part of a workpiece 602 containing additional die 601a. The die 601 and the workpiece 602 may be implemented as any of the examples disclosed in reference to the die 101 and the workpiece 102 of FIG. 1A. The die 601 and the additional die 601a have terminals 603 at a component surface 604 of the die 601 and component surfaces 604a of the additional die 601a. The terminals 603 are electrically conductive.

Referring to FIG. 6B, an interface layer 643 is formed on the component surface 604 of the die 601, and on the component surfaces 604a of the additional die 601a. The interface layer 643 is electrically conductive, and directly contacts the terminals 603. The interface layer 643 may include, for example, the sublayers disclosed in reference to the interface layer 543 of FIG. 5B. A pillar mask 644 is formed over the interface layer 643. The pillar mask 644 has pillar holes 645 which extend through the pillar mask 644 and expose the interface layer 643 over the terminals 603. The pillar mask 644 may include a photoresist and may be formed by a photolithographic process. Alternatively, the pillar mask 644 may include organic polymer and may be formed by an additive process, such as a material extrusion process or a material jetting process. The pillar mask 644 may be 1 micron to 100 microns thick, for example.

Pillars 605 are formed on the interface layer 643 in the pillar holes 645 of the pillar mask 644 by a pillar plating process using a pillar plating bath 646. The pillar plating process may be implemented as an electroplating process using the interface layer 643 as a cathode. The pillars 605 may include electrically conductive material as disclosed in reference to the pillars 505 of FIG. 5C. The pillars 605 are electrically conductive and make electrical contact to the interface layer 643. The pillars 605 of this example may have widths of 2 to 50 microns. FIG. 6B depicts the pillars 605 having equal widths. In an alternate version of this example, the pillars 605 may have different widths, to accommodate different currents during operation of the microelectronic device 600. The pillars 605 of this example extend proximate to a top surface of the pillar mask 644, within a vertical distance equal to the width of the pillars 605. After the pillars 605 are formed, the microelectronic device 600 is removed from the pillar plating bath 646. The pillar mask 644 is left in place for subsequent fabrication steps.

Referring to FIG. 6C, an external lead lamina 651 is provided. The external lead lamina 651 includes a dielectric lamination stack 652 and external leads 616 which extend through the dielectric lamination stack 652. The dielectric lamination stack 652 is electrically non-conductive, and may include epoxy, polyester, or silicone, for example, and may be reinforced with fiberglass. The external leads 616 are electrically conductive. The external lead lamina 651 may have access vias 667 extending through the dielectric lamination stack 652. The external lead lamina 651 may include spacers 653 to provide a desired separation between the external leads 616 and the pillars 605. The external lead lamina 651 is aligned with the microelectronic device 600 and the additional microelectronic devices 600a, and brought into contact with the pillar mask 644.

FIG. 6D is a cross section of the external lead lamina 651 in contact with the pillar mask 644. The external leads 616 have connection surfaces 621 at an exterior of the microelectronic device 600 and the additional microelectronic devices 600a, and have plating surfaces 654 at an interior surface of the external lead lamina 651, located opposite from the exterior surface. The plating surfaces 654 are aligned with top surfaces 622 of the pillars 605, as depicted in FIG. 6D.

A cathode bus 655 is brought into contact with the connection surfaces 621 of the external leads 616. The cathode bus 655 includes an electrically conductive material, such as a polymer matrix with metal particles, or an anisotropic conductive tape and a metal sheet, as disclosed in reference to the cathode bus 555 of FIG. 5H. An isolation cover 669, which is electrically non-conductive, covers and isolates the cathode bus 655. The isolation cover 669 may include polymer material, and may be formed by a tape application process, a spray process, or a material extrusion process, for example. The cathode bus 655 and the isolation cover 669 of this example have openings which align with the access vias 667, as depicted in FIG. 6D.

Referring to FIG. 6E, a plating solution 661 is introduced between the external lead lamina 651 and the microelectronic device 600 and the additional microelectronic devices 600a, contacting the top surfaces 622 of the pillars 605 and the plating surfaces 654 of the external leads 616. The access vias 667 through the external lead lamina 651 may facilitate circulation of the plating solution 661 between the external lead lamina 651 and the microelectronic device 600 and the additional microelectronic devices 600a. A first plating bias 662 is applied between the plating solution 661 and the pillars 605, through the interface layer 643. A second plating bias 663 is applied between the plating solution 661 and the external leads 616 through the cathode bus 655.

A metal joint plating process is performed, in which current flows through the plating solution 661 and through the top surfaces 622 into the pillars 605, as a result of the first plating bias 662 being applied, and through the plating solution 661 and through the plating surfaces 654 into the external leads 616, as a result of the second plating bias 663 being applied. The metal joint plating process forms plated metal joints 664 between the pillars 605 and the external leads 616. The plating solution 661 may have a composition similar to that disclosed in reference to the plating solution 561 of FIG. 5I. The plating solution 661 is removed after the plated metal joints 664 are completely formed. The cathode bus 655 and the isolation cover 669 are subsequently removed. The isolation cover 669 may be removed by peeling or spraying with organic solvents. Similarly, the cathode bus 655 may be removed by peeling or spraying with organic solvents.

Referring to FIG. 6F, the pillar mask 644 of FIG. 6E is removed. The pillar mask 644 may be removed by as disclosed in reference to removal of the pillar mask 544 of FIG. 5L, for example. The access vias 667 through the external lead lamina 651 may facilitate circulation of solvents and cleaning agents for removal of the pillar mask 644. Other methods for removing the pillar mask 644 are within the scope of this example.

The interface layer 643 is removed where exposed by the pillars 605. The interface layer 643 may be removed by a wet etch solution 666 as disclosed in reference to removal of the interface layer 543 of FIG. 5M. The access vias 667 through the external lead lamina 651 may similarly facilitate circulation of the wet etch solution 666 for removal of the interface layer 643. Other methods for removing the interface layer 643 are within the scope of this example.

Referring to FIG. 6G, a package structure 612 is formed between the external lead lamina 651 and the microelectronic device 600 and the additional microelectronic devices 600a. The package structure 612 is electrically non-conductive, and may include, for example, epoxy, BCB, silicone, polyurethane, or polyester. Other non-conductive material for the package structure 612 is within the scope of this example. The package structure 612 may be formed by injection molding, reaction injection molding, or other process. The access vias 667 through the external lead lamina 651 may facilitate injection of material for the package structure 612 between the external lead lamina 651 and the microelectronic device 600 and the additional microelectronic devices 600a.

Referring to FIG. 6H, the microelectronic device 600 is singulated from the additional microelectronic devices 600a by a singulation process, such as a saw process. The singulation process may include one or more singulation operations, such as a first saw operation to cut through the external lead lamina 651 and a second saw operation to cut through the workpiece 602.

Referring to FIG. 6I, a package coating 633 may optionally be formed on exposed surfaces of the die 601. The package coating 633 may be electrically non-conductive, to electrically and optically isolate the die 601. The pillars 605, the interface layer 643 between the pillars 605 and the terminals 603, the external leads 616, and the plated metal joint 664 between the pillars 605 and the external leads 616 are parts of package leads 620 of the microelectronic device 600. The package structure 612 extends further from the component surface 604 than the pillar 605. The package leads 620 are advantageously free of a solder joint, and free of metals which may form intermetallic compounds with copper, accruing the advantages disclosed in reference to FIG. 1M.

Various features of the examples disclosed herein may be combined in other methods of forming example microelectronic device. For example, the package plate 111 of FIG. 1D may be applied to the workpieces in the other examples disclosed herein. In another example, the barrier layers 231 of FIG. 2G may be formed on any of the external leads in the other examples disclosed herein. In a further example, the anchor cavity 440 of FIG. 4A may be formed used in the other examples disclosed herein.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a die having a component surface;
a package structure on the component surface, the package structure being electrically non-conductive;
a package lead directly contacting the die and extending through the package structure to an exterior of the microelectronic device; wherein:
the package lead is electrically conductive;
the package lead includes a pillar electrically coupled to the die and extending partway through the package structure, the pillar being electrically conductive;
the package lead includes an external lead electrically coupled to the pillar and extending to the exterior of the microelectronic device, the package lead being electrically conductive; and
the package lead is free of tin, lead, indium, and bismuth.

2. The microelectronic device of claim 1, wherein the package structure extends further from the component surface than the pillar.

3. The microelectronic device of claim 1, wherein the package lead includes an interface layer between the pillar and the external lead, the interface layer being electrically conductive.

4. The microelectronic device of claim 3, wherein the interface layer includes a metal selected from the group consisting of titanium, tungsten, and tantalum.

5. The microelectronic device of claim 1, wherein the package lead includes a plated metal joint between the pillar and the external lead, the plated metal joint being electrically conductive.

6. The microelectronic device of claim 5, wherein the external lead extends through an external lead lamina of the microelectronic device, the external lead lamina contacting the package structure.

7. The microelectronic device of claim 6, wherein the external lead lamina includes a dielectric lamination stack contacting the external lead, the dielectric lamination stack being electrically non-conductive.

8. The microelectronic device of claim 1, wherein the pillar includes more than 50 weight percent copper.

9. The microelectronic device of claim 1, wherein the external lead includes more than 50 weight percent copper.

10. The microelectronic device of claim 1, wherein a connection surface of the external lead at an exterior of the microelectronic device is greater than a top surface of the pillar.

11. The microelectronic device of claim 1, wherein a connection surface of the external lead at an exterior of the microelectronic device is laterally offset, in a direction parallel to the component surface of the die, from a top surface of the pillar.

12. A method of forming a microelectronic device, comprising:
providing a die having a terminal at a connection surface of the die, and having a pillar electrically coupled to the terminal, the pillar being electrically conductive;
forming a package structure on the die, the package structure being electrically non-conductive, contacting the die, and covering the pillar;
forming an access cavity in the package structure, the access cavity exposing the pillar;
forming an external lead mask on the package structure, the external lead mask exposing the access cavity; and
forming an external lead in the access cavity where exposed by the external lead mask, the external lead contacting the pillar and extending to an exterior of the microelectronic device, the external lead being electrically conductive; wherein:
the pillar and the external lead are parts of a package lead of the microelectronic device;
the package lead is electrically conductive; and
the package lead is free of tin, lead, indium, and bismuth.

13. The method of claim 12, further comprising:
forming an interface layer over the package structure after forming the access cavity and prior to forming the external lead mask; wherein:
the interface layer is electrically conductive;
the interface layer extends into the access cavity and contacts the pillar;
the external lead mask is formed on the interface layer; and
forming the external lead is performed by a plating process on the interface layer;
removing the external lead mask after forming the external lead; and
removing the interface layer where exposed by the external lead.

14. The method of claim 12, further comprising singulating the die from a workpiece prior to forming the package structure.

15. The method of claim 12, further comprising singulating the die from a workpiece after forming the external lead.

16. A method of forming a microelectronic device, comprising:
providing a die having a terminal at a component surface of the die, and having a pillar electrically coupled to the terminal, the pillar being electrically conductive;
providing an external lead lamina containing an external lead extending through a dielectric lamination stack, the external lead being electrically conductive, the external lead having a plating surface, the external lead having a connection surface at an exterior of the microelectronic device;
aligning the plating surface of the external lead with a top surface of the pillar;
disposing a plating solution between the external lead lamina and the die, the plating solution contacting the plating surface of the external lead and the top surface of the pillar; and
forming a plated metal joint that connects the plating surface of the external lead to the top surface of the pillar by flowing current through the external lead and through the pillar.

17. The method of claim 16, further comprising forming a package structure between the external lead lamina and the die, and contacting the plated metal joint, the package structure being electrically non-conductive.

18. The method of claim 17, wherein:
providing the die includes:
forming an interface layer on the component surface of the die contacting the terminal, the interface layer being electrically conductive;
forming a pillar mask on the interface layer, the pillar mask exposing the interface layer in an area for the pillar; and
forming the pillar by plating metal on the interface layer where exposed by the pillar mask; and
further comprising:
removing the pillar mask after forming the plated metal joint and prior to forming the package structure; and
removing the interface layer where exposed by the pillar after removing the pillar mask.

19. The method of claim 18, further comprising singulating the die from a workpiece prior to forming the plated metal joint.

20. The method of claim 18, further comprising singulating the die from a workpiece after forming the plated metal joint.
